(19) United States
(12) Patent Application Publication
(10) Pub. No.: US 2025/0208272 A1
(43) Pub. Date: Jun. 26, 2025

(54) OPTICAL DETECTION DEVICE

(71) Applicant: SONY SEMICONDUCTOR SOLUTIONS CORPORATION, KANAGAWA (JP)

(72) Inventor: MASAMUNE HAMAMATSU, KANAGAWA (JP)

(21) Appl. No.: 18/849,664

(22) PCT Filed: Mar. 27, 2023
(86) PCT No.: PCT/JP2023/012076

§ 371 Date: Sep. 23, 2024

(30) Foreign Application Priority Data
Apr. 1, 2022 (JP) 2022-062138

(51) Int. Cl. G01S 7/497; G01S 7/481; G01S 7/484; G01S 7/4865; G01S 17/10

(52) U.S. Cl. CPC G01S 7/497; G01S 7/4814; G01S 7/484; G01S 7/4865; G01S 17/10

(57) ABSTRACT

[Object]

Variations of light emitting elements and light receiving elements are accurately correctable.

[Solving Means]

An optical detection device includes a plurality of light emitting elements each of which emits a first light pulse signal, a plurality of light propagation members that propagate the first light pulse signals emitted from the plurality of light emitting elements, a plurality of first light receiving elements that receive the first light pulse signals propagated through the plurality of light propagation members, a plurality of second light receiving elements that receive reflection light pulse signals obtained by the first light pulse signals emitted from the plurality of light emitting elements being reflected on an object, and a plurality of light guide members that guide the first light pulse signals emitted from the plurality of light emitting elements to the plurality of light propagation members.

### TECHNICAL FIELD

The present disclosure relates to an optical detection device.

### BACKGROUND ART

For example, a ToF (Time of Flight) sensor which applies a light pulse signal to an object and receives a reflection light signal reflected on the object, to measure a distance to the object, and a photocounter which counts the number of photons contained in the reflection light signal are known.

In the case of using a light emitting module containing a plurality of light emitting elements as a light emission source, some of the plurality of light emitting elements are sequentially shifted during light emission therefrom to achieve distance measurement and photocounting.

For measuring a distance to an object by a light pulse signal emitted from a light emitting element toward the object and a reflection light pulse signal reflected from the object and received by a light receiving element, it is necessary to accurately detect light emission timing of the light emitting element. Accordingly, there has been disclosed such a technology which provides a reflection member in the vicinity of the light emitting element, and also provides an additional light receiving element receiving a light pulse signal reflected on the reflection member, to detect light emission timing by this light receiving element (see PTL 1).
(see PTL 1).

### CITATION LIST

### Patent Literature

[PTL 1]
US Published Application No. 2016/0033644A1

### SUMMARY

### Technical Problems

However, in a case of a configuration where a plurality of light receiving elements are provided to receive reflection light pulse signals from an object, a plurality of light receiving elements are also required to detect light emission timing. This configuration thus raises component costs, and requires a sufficient installation location.

In addition, in a case where a plurality of light emitting elements are provided, a length of time required for each of the plurality of light emitting elements to start emission of light after being instructed to emit light may be varied according to manufacturing variations and environmental conditions such as temperature. Similarly, in a case where a plurality of light receiving elements are provided, a length of time required for each of the light receiving elements to output a light reception signal after a reflection light signal has entered into each of the light receiving elements may be varied according to manufacturing variations and environmental conditions such as temperature.

Accordingly, the present disclosure provides an optical detection device capable of accurately correcting variations of light emitting elements and light receiving elements.

### Solution to Problems

For solving the abovementioned problems, the present disclosure provides an optical detection device including a plurality of light emitting elements each of which emits a first light pulse signal, a plurality of light propagation members that propagate the first light pulse signals emitted from the plurality of light emitting elements, a plurality of first light receiving elements that receive the first light pulse signals propagated through the plurality of light propagation members, a plurality of second light receiving elements that receive reflection light pulse signals obtained by the first light pulse signals emitted from the plurality of light emitting elements being reflected on an object, and a plurality of light guide members that guide the first light pulse signals emitted from the plurality of light emitting elements to the plurality of light propagation members.

Each of the plurality of light emitting elements may include a laminate that includes an active layer and a light extraction portion, and a part of the first light pulse signal emitted from the corresponding light extraction portion may be introduced into each of the plurality of light propagation members.

The optical detection device may further include a first substrate that supports a plurality of the laminates and transmits the first light pulse signal emitted from each of the light extraction portions, and a plurality of electrodes disposed at ends of the plurality of laminates on a side opposite to the light extraction portions. The plurality of light propagation members may be disposed along the first substrate.

The optical detection device may further include a first substrate that is disposed on a side opposite to the light extraction portions of a plurality of the laminates and supports the plurality of laminates, and a plurality of electrodes that are disposed on the first substrate and supply voltage to the plurality of laminates. The plurality of light propagation members may be disposed along the first substrate.

Each of the plurality of light emitting elements may include a laminate that includes an active layer and a light extraction portion, and each of the plurality of light propagation members may propagate a part of the first light pulse signal emitted from the corresponding active layer.

The optical detection device may further include a first substrate that supports the plurality of laminates and transmits the first light pulse signal emitted from each of the light extraction portions, and a plurality of electrodes disposed at ends of the plurality of laminates on a side opposite to the light extraction portions. The plurality of light propagation members may be disposed along a plurality of the active layers.

The optical detection device may further include a first substrate that is disposed on a side opposite to the light extraction portions of a plurality of the laminates and supports the plurality of laminates, and a plurality of electrodes disposed on the first substrate. The plurality of light propagation members may be disposed along a plurality of the active layers.

Each of the plurality of light emitting elements may include a laminate that includes an active layer and a light extraction portion, and a light reflection member disposed on a side opposite to the light extraction portion with the active layer interposed between the light reflection member and the light extraction portion, and each of the plurality of light propagation members may propagate the first light pulse signal emitted from an opening formed at a part of the corresponding light reflection member.

The optical detection device may further include a first substrate that supports the plurality of laminates and transmits the first light pulse signal emitted from each of the light extraction portions, a plurality of electrodes disposed at ends of the plurality of laminates on a side opposite to the light extraction portions, and a second substrate that generates voltage to be supplied to the plurality of electrodes. The plurality of light propagation members may be disposed on the second substrate.

The optical detection may further include a first substrate that is disposed on a side opposite to the light extraction portions of a plurality of the laminates and supports the plurality of laminates, a plurality of electrodes disposed on the first substrate, and a second substrate that generates voltage to be supplied to the plurality of electrodes. The plurality of light propagation members may be disposed on the second substrate.

The optical detection may further include a light emission substrate where the plurality of light emitting elements are disposed, and a light reception substrate where the plurality of first light receiving elements and the plurality of second light receiving elements are disposed. Each of the plurality of light propagation members may be disposed in such a manner as to extend over the light emission substrate and the light reception substrate.

The optical detection device may further include a substrate where the plurality of light emitting elements, the plurality of first light receiving elements, and the plurality of second light receiving elements are disposed. The plurality of light propagation members may be disposed on the substrate.

The optical detection device may further include a light emission substrate where the plurality of light emitting elements and the plurality of first light receiving elements are disposed, and a light reception substrate where the plurality of second light receiving elements are disposed. Each of the plurality of light propagation members may be disposed in such a manner as to extend over the light emission substrate and the light reception substrate.

The plurality of first light receiving elements may be disposed closer to the plurality of light emitting elements than the plurality of second light receiving elements, and the plurality of light propagation members may be disposed from a region containing the plurality of light emitting elements to a region containing the plurality of first light receiving elements.

The optical detection device may further include a light shielding member that shields light to prevent entrance of the first light pulse signals propagated through the plurality of light propagation members into the plurality of second light receiving elements.

Each of the plurality of light guide members may have a grating coupler.

Each of the plurality of light guide members may switch the first light pulse signals emitted from two or more of the light emitting elements to propagate the first light pulse signals.

The optical detection device may further include two or more optical switches each of which is connected to the corresponding one of the plurality of light guide members. The first light pulse signals emitted from the two or more light emitting elements may be sequentially introduced into the corresponding light guide member by sequentially turning on the two or more optical switches one by one.

Each of the first light receiving elements may include an SPAD (Single Photon Avalanche photodiode), an SiPM (Silicon Photomultiplier), an iToF (indirect Time of Flight) sensor, or a photon count sensor.

Each of the light propagation members may have an optical waveguide, or an optical fiber and an optical connector.

### BRIEF DESCRIPTION OF DRAWINGS

FIG. 1 is a block diagram illustrating a schematic structure of a distance measuring system including an optical detection device according to a first embodiment.

FIG. 2 is a schematic plan diagram of a light emission unit and a pixel array unit according to the first embodiment.

FIG. 3 is a cross-sectional diagram illustrating a positional relation between light emitting elements and optical waveguides.

FIG. 4 is a cross-sectional diagram illustrating a first modification of FIG. 3.

FIG. 5 is a cross-sectional diagram illustrating a second modification of FIG. 3.

FIG. 6A is a cross-sectional diagram of a more specific illustration of a cross-sectional structure in FIG. 4 where the optical waveguide is provided near a light extraction portion of the light emitting element.

FIG. 6B is a cross-sectional diagram illustrating a modification of FIG. 6A.

FIG. 7 is a cross-sectional diagram of a more specific illustration of a cross-sectional structure in FIG. 5 where the optical waveguide is provided near an active layer of the light emitting element.

FIG. 8A is a cross-sectional diagram of a more specific illustration of a cross-sectional structure in FIG. 6 where the optical waveguide is provided on the side opposite to the light extraction portion of the light emitting element.

FIG. 8B is a cross-sectional diagram illustrating a modification of FIG. 8A.

FIG. 9 is a cross-sectional diagram of a front-surface type VCSEL where the optical waveguide is provided near the light extraction portion of the light emitting element.

FIG. 10A is a cross-sectional diagram of a front-surface type VCSEL where the optical waveguide is provided near the active layer of the light emitting element.

FIG. 10B is a cross-sectional diagram illustrating a first modification of FIG. 10A.

FIG. 10C is a cross-sectional diagram illustrating a second modification of FIG. 10A.

FIG. 11A is a cross-sectional diagram of a front-surface type VCSEL where the optical waveguide is provided on the side opposite to the light extraction portion of the light emitting element.

FIG. 11B is a cross-sectional diagram illustrating a modification of FIG. 11A.

FIG. 12 is a cross-sectional diagram illustrating a structure around the light emission unit and a light reception unit.

FIG. 13 is a cross-sectional diagram illustrating a first modification of FIG. 12.

FIG. 14 is a cross-sectional diagram illustrating a second modification of FIG. 12.

FIG. 15A is a diagram illustrating optical coupling means including a grating coupler.

FIG. 15B is a schematic cross-sectional diagram illustrating a first modification of the light coupling means.

FIG. 15C is a schematic cross-sectional diagram illustrating a second modification of the light coupling means.

FIG. 15D is a schematic cross-sectional diagram illustrating a third modification of the light coupling means.

FIG. 15E is a schematic cross-sectional diagram illustrating a fourth modification of the light coupling means.

FIG. 16A is a schematic cross-sectional diagram illustrating an example where a reference pixel is disposed on an LDD substrate where the light emission unit is disposed.

FIG. 16B is a schematic cross-sectional diagram illustrating a first modification of FIG. 16A.

FIG. 16C is a schematic cross-sectional diagram illustrating a second modification of FIG. 16A.

FIG. 16D is a schematic cross-sectional diagram illustrating a third modification of FIG. 16A.

FIG. 17A is a schematic cross-sectional diagram illustrating an example where the reference pixel is disposed on a substrate different from the LDD substrate.

FIG. 17B is a schematic cross-sectional diagram illustrating a first modification of FIG. 17A.

FIG. 17C is a schematic cross-sectional diagram illustrating a second modification of FIG. 17A.

FIG. 17D is a schematic cross-sectional diagram illustrating a third modification of FIG. 17A.

FIG. 18 is a schematic cross-sectional diagram illustrating an example where the light emitting element, the reference pixel, and a distance measurement pixel are disposed on the LDD substrate.

FIG. 19A is a diagram illustrating an example where a light propagation member including an optical fiber and optical connectors is disposed between the light emitting element and the reference pixel.

FIG. 19B is a diagram illustrating a modification of FIG. 19A.

FIG. 20A is a diagram illustrating a first example of a light pulse signal transmission and reception method between a substrate of the light emission unit and a substrate of the light reception unit.

FIG. 20B is a diagram illustrating a second example of the light pulse signal transmission and reception method between the substrate of the light emission unit and the substrate of the light reception unit.

FIG. 20C is a diagram illustrating a third example of the light pulse signal transmission and reception method between the substrate of the light emission unit and the substrate of the light reception unit.

FIG. 21A is a diagram illustrating an example which introduces light into the reference pixel by using a grating coupler.

FIG. 21B is a diagram illustrating a first modification of FIG. 21A.

FIG. 21C is a diagram illustrating a second modification of FIG. 21A.

FIG. 22A is a diagram illustrating an example which adopts an SPAD as the light receiving element constituting the reference pixel.

FIG. 22B is a diagram illustrating an example of dToF which adopts an SiPM as the reference pixel.

FIG. 22C is a diagram illustrating an example of iToF which adopts an SiPM as the reference pixel.

FIG. 22D is a diagram illustrating an example of photon counting which adopts an SiPM as the reference pixel.

FIG. 23A is a plan diagram schematically illustrating optical switches disposed between the respective light emitting elements 5 and the corresponding optical waveguide.

FIG. 23B is a plan diagram illustrating an enlarged structure around the optical switch.

FIG. 24A is a perspective diagram of an optical gate switch which is a first example of the optical switch.

FIG. 24B is a perspective diagram of a Mach-Zehnder interference type optical switch which is a second example of the optical switch.

FIG. 24C is a perspective diagram of a directional coupling type optical switch which is a third example of the optical switch.

FIG. 25 is a block diagram depicting an example of schematic configuration of a vehicle control system.

FIG. 26 is a diagram of assistance in explaining an example of installation positions of an outside-vehicle information detecting section and an imaging section.

### DESCRIPTION OF EMBODIMENTS

An optical detection device according to embodiments will hereinafter be described with reference to the drawings. While a main constituent part of the optical detection device will mainly be explained hereinafter, the optical detection device may include constituent parts and functions neither depicted nor described. It is not intended that the constituent parts and the functions neither depicted nor described be excluded from the following description.

### First Embodiment

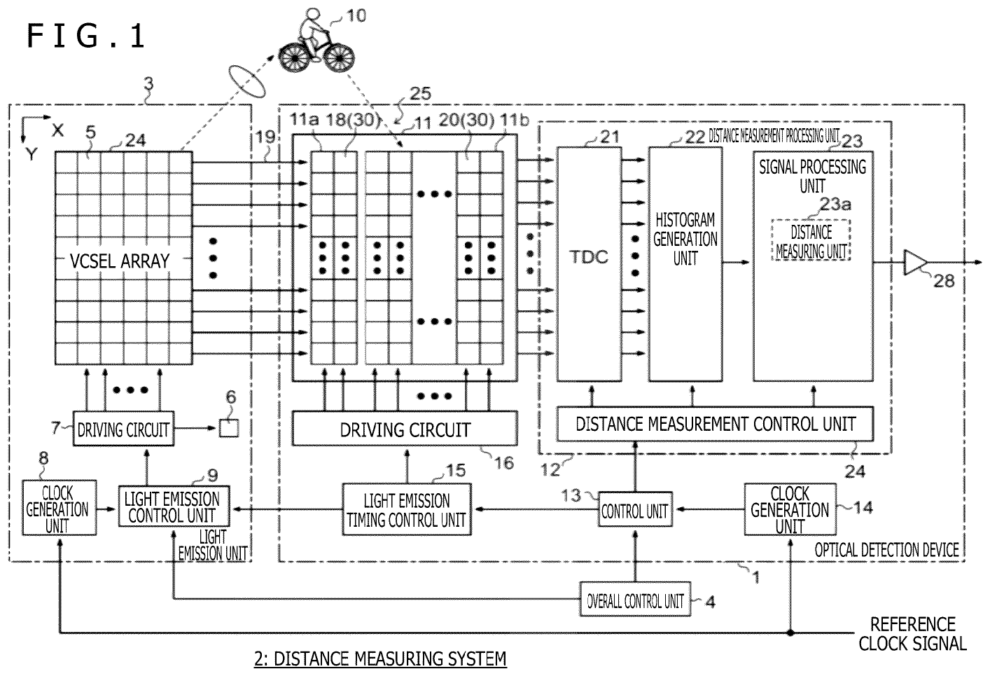

FIG. 1 is a block diagram illustrating a schematic configuration of a distance measuring system 2 which includes an optical detection device 1 according to a first embodiment. The distance measuring system 2 illustrated in FIG. 1 includes the optical detection device 1, a light emission unit 3, and an overall control unit 4. The distance measuring system 2 in FIG. 1 performs a distance measuring process by a dToF (direct Time of Flight) method. The optical detection device 1 includes a light reception unit 25. The light emission unit 3 and the light reception unit 25 will be abbreviated as Tx and Rx, respectively, in the present description and the drawings in some cases.

The light emission unit 3 includes a plurality of light emitting elements 5, a light emission source 6, a driving circuit 7, a clock generation unit 8, and a light emission control unit 9.

The plurality of light emitting elements 5 are formed in such a manner as to be arranged in each of a first direction X and a second direction Y crossing each other. The plurality of light emitting elements 5 repetitively emit light emission pulse signals (Tx pulse signals) at predetermined time intervals. The light emission unit 3 is capable of scanning light signals emitted from the plurality of light emitting elements 5, on a predetermined two-dimensional space. The specific method for scanning the light signals is not particularly limited to any kind.

For example, each of the light emitting elements 5 is a VCSEL (Vertical Cavity Surface Emitting Laser). Mainly described hereinafter will be an example which uses a VCSEL array 17 where the plurality of light emitting elements 5 are arranged on the same substrate. The first direction (horizontal direction) X and the second direction (vertical direction) Y in each of which the plurality of light emitting elements 5 are arranged will hereinafter be referred to as a column and a row, respectively, in some cases. One row of the plurality of light emitting elements 5 arranged in the first direction X will be referred to as a light emitting element row or a light emitting element group. An optical waveguide 19 extending in the first direction X is connected to the corresponding light emitting element row. A plurality of optical waveguides 19 are disposed in correspondence with a plurality of light emitting element rows arranged in the second direction Y. The two or more light emitting elements 5 within each of the light emitting element rows are capable of sequentially introducing light pulse signals into the corresponding optical waveguide 19. In such a manner, simultaneous introduction of two or more light pulse signals from the two or more light emitting elements 5 into the optical waveguide 19 is prohibited. Accordingly, light pulse signals emitted from the respective light emitting elements 5 are sequentially propagated through the corresponding optical waveguide 19.

A plurality of light emitting pixel columns arranged in the second direction Y are capable of simultaneously introducing light pulse signals into a plurality of optical waveguides 19. Accordingly, the plurality of optical waveguides 19 propagate light pulse signals received from the different light emitting elements 5, at the same timing.

The light emission source 6 is provided separately from the plurality of light emitting elements 5, and used for correcting time differences in light reception timing between light receiving elements 30 described below. The light emission source 6 typically emits light pulse signals before starting a distance measuring process by causing light emission from a plurality of light emitting elements 5. A light emission region of the light emission source 6 contains an entire light reception region of the light reception unit 25. Accordingly, all of the light receiving elements 30 in the light reception unit 25 can receive light pulse signals from the light emission source 6.

The light emission source 6 is not a required constituent member. The light emission source 6 may be eliminated if the time differences in light reception timing between the light receiving elements 30 need not be corrected.

The driving circuit 7 drives the plurality of light emitting elements 5 and the light emission source 6 according to a control signal from the light emission control unit 9. For example, the driving circuit 7 controls at least either light emission timing or light emission waveforms of the light pulse signals in accordance with the control signal from the light emission control unit 9. More specifically, the driving circuit 7 controls a voltage level of voltage to be applied to anodes or cathodes of the plurality of light emitting elements 5 according to the control signal from the light emission control unit 9 to control at least one factor selected from signal intensity, light peak intensity, a pulse width, rising edge timing, falling edge timing, and a slew rate of each of the light pulse signals received from the plurality of light emitting elements 5.

The clock generation unit 8 generates a clock signal synchronized with a reference clock signal. For example, the reference clock signal is a signal input from the outside of the distance measuring system 2. Alternatively, the reference clock signal may be generated inside the distance measuring system 2.

The light emission control unit 9 generates a control signal synchronized with the clock signal and used to control at least either light emission timing or light emission waveforms of the respective light emitting elements 5. The driving circuit 7 described above drives the plurality of light emitting elements 5 and the light emission source 6 according to the control signal output from the light emission control unit 9.

The overall control unit 4 controls the light emission unit 3 and the optical detection device 1. At least either the light emission unit 3 or the overall control unit 4 may be provided integrally with the optical detection device 1.

The optical detection device 1 includes a pixel array unit 11, a distance measurement processing unit 12, a control unit 13, a clock generation unit 14, a light emission timing control unit 15, and a driving circuit 16. The pixel array unit 11 constitutes the light reception unit 25.

The pixel array unit 11 includes a reference pixel array unit 11a and a distance measurement pixel array unit 11b. The reference pixel array unit 11a includes a plurality of reference pixels 18 arranged in at least the second direction Y. The plurality of reference pixels 18 are associated with a plurality of optical waveguides 19. More specifically, each of the plurality of reference pixels 18 arranged in the second direction Y receives light pulse signals propagated through the corresponding optical waveguide 19.

As will be described below, the plurality of reference pixels 18 receive light pulse signals emitted from the plurality of light emitting elements 5 arranged in the second direction Y, via the plurality of optical waveguides 19. In such a manner, the plurality of reference pixels 18 are capable of directly receiving light pulse signals from the plurality of light emitting elements 5. Accordingly, the plurality of reference pixels 18 are capable of accurately detecting light emission timing of the plurality of light emitting elements 5. The plurality of reference pixels 18 receive light signals propagated through the plurality of optical waveguides 19, and output voltage signals in response to arrival of photons. Moreover, the plurality of reference pixels 18 receive light pulse signals from the light emission source 6, and output voltage signals in response to arrival of photons.

The distance measurement pixel array unit 11b has a plurality of distance measurement pixels 20 that are arranged in each of the first direction X and the second direction Y. The plurality of distance measurement pixels 20 receive reflection light signals from an object 10. The plurality of distance measurement pixels 20 output voltage signals in response to arrival of photons. Light intensity of the reflection light signals is also detectable by averaging results of repetitive reception of the reflection light signals by the respective distance measurement pixels 20. Described hereinafter will be an example where the plurality of reference pixels 18 and the plurality of distance measurement pixels 20 output voltage signals in response to arrival of photons.

Each of the plurality of reference pixels 18 and the plurality of distance measurement pixels 20 has the light receiving element 30. For example, each of the light receiving elements 30 is an SPAD (Single Photon Avalanche photo Diode) 30. Each of the reference pixels 18 and the distance measurement pixels 20 may have an unillustrated quenching circuit. In an initial state, the quenching circuit supplies reverse bias voltage, which has a potential difference in excess of breakdown voltage, between an anode and a cathode of the SPAD 30. After the SPAD 30 detects a photon, the driving circuit 16 supplies the reverse bias voltage to the SPAD 30 via the corresponding quenching circuit to prepare for detection of the next reflection light pulse signal (Rx pulse signal).

The distance measurement processing unit 12 includes time digital converters (TDCs) 21, a histogram generation unit 22, a signal processing unit 23, and a distance measurement control unit 24.

Each of the TDCs 21 generates a time digital signal with predetermined time resolution according to a light reception time of a reflection light pulse signal received by the SPAD 30. In reference to the time digital signals generated by the TDCs 21, the histogram generation unit 22 generates a histogram having a bin width corresponding to the time resolution of the TDCs 21. The bin width refers to a width of each frequency unit constituting the histogram. Higher time resolution of the TDCs 21 can reduce the bin width more, and enables generation of a histogram more accurately reflecting the time frequency of reception of the Rx pulse signal.

The signal processing unit 23 has a distance measuring unit 23a. The distance measuring unit 23a calculates a distance to the object 10 by using the position of the center of gravity of the Rx pulse signal calculated from the histogram, for example, and outputs the calculated distance via an output buffer 28. As will be described below, the signal processing unit 23 calculates time differences in light emission timing between the plurality of light emitting elements 5, and generates correction signals for correcting the time differences in light emission timing between the plurality of light emitting elements 5 according to the calculated time differences.

The control unit 13 controls processing operations of the respective units in the optical detection device 1. The distance measurement control unit 24 controls the TDCs 21, the histogram generation unit 22, and the signal processing unit 23 in the distance measurement processing unit 12. The light emission timing control unit 15 controls the light emission control unit 9 in the light emission unit 3, and controls the driving circuit 16. For example, the driving circuit 16 performs quenching control for restoring cathode voltage to original voltage at the time of a drop of cathode voltage in response to detection of light by the plurality of reference pixels 18 and the plurality of distance measurement pixels 20 in the pixel array unit 11.

The clock generation unit 14 generates a clock signal to be used by each of the TDCs 21 and the histogram generation unit 22. For example, the clock generation unit 14 generates the clock signal by using an unillustrated PLL circuit.

### (Details of Light Emission Unit 3 and Pixel Array Unit 11)

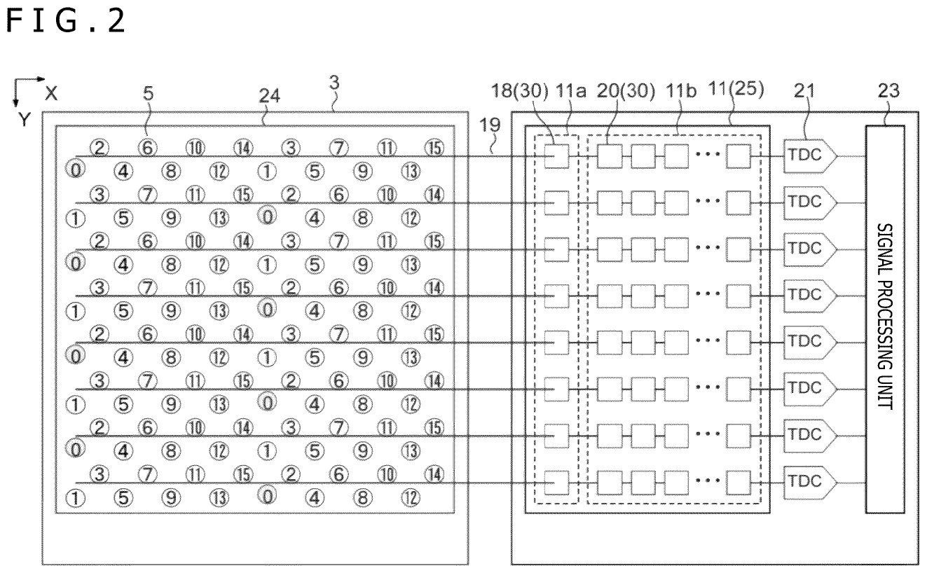

FIG. 2 is a schematic plan diagram of the light emission unit 3 and the pixel array unit 11 according to the first embodiment. The light emission unit 3 in FIG. 2 includes the VCSEL array 17 where a plurality of light emitting elements 5 (VCSEL) are arranged.

While the VCSEL array 17 in FIG. 2 includes 16 light emitting elements 5 in the first direction X (horizontal direction) and eight light emitting elements 5 in the second direction Y (vertical direction), this configuration is presented only by way of example. Each of the numbers of the light emitting elements 5 arranged in the first direction X and the second direction Y may be any number.

Eight optical waveguides 19 extending in the first direction X are provided on the VCSEL array 17. The 16 light emitting elements 5 are arranged in a staggered shape along each of the optical waveguides 19. Each of the 16 light emitting elements 5 is capable of introducing a light pulse signal into the corresponding optical waveguide 19. However, simultaneous introduction of light pulse signals from a plurality of light emitting elements 5 into the optical waveguide 19 is prohibited. Accordingly, the 16 light emitting elements 5 sequentially introduce light pulse signals into the corresponding optical waveguide 19.

The four light emitting elements 5 located at every other positions among the eight light emitting elements 5 arranged in the second direction Y (vertical direction) simultaneously emit light pulse signals. Numerals 0 to 15 in FIG. 2 indicate light emission timing of the plurality of light emitting elements 5. A set of the eight light emitting elements 5 indicated by “0” emits light at the same timing, and each following set of the eight light emitting elements 5 indicated by the same numeral emits light at the same timing in an ascending order of the numerals.

As described above, in the example illustrated in FIG. 2, the 16×8=108 light emitting elements 5 sequentially emit light for each set of the eight light emitting elements 5 at timing divided into 16 sections. Respective light pulse signals emitted from the set of the eight light emitting elements 5 simultaneously emitting light are propagated through the different optical waveguides 19.

The pixel array unit 11 in the light reception unit 25 includes a plurality of reference pixels 18 and a plurality of distance measurement pixels 20. Each of the reference pixels 18 and the distance measurement pixels 20 has the same structure, and includes the light receiving element 30 having the same structure and electrical characteristics. However, as will be described below, variations in electrical characteristics may be produced in the light receiving elements 30 constituting the respective reference pixels 18 and the respective distance measurement pixels 20 due to variations in manufacturing process or the like.

Each of the optical waveguides 19 on the VCSEL array 17 reaches a position close to the corresponding reference pixel 18 in the light reception unit 25. A light pulse signal propagated through each of the optical waveguides 19 is introduced into the corresponding reference pixel 18. In such a manner, each of the reference pixels 18 can detect light emission timing of the corresponding light emitting element 5 substantially in real time. Moreover, substantially no light loss is considered to be produced in the optical waveguides 19. Accordingly, each of the reference pixels 18 can detect light emission intensity of the corresponding light emitting element 5.

As the plurality of distance measurement pixels 20, the same number of the distance measurement pixels 20 as the number of the reference pixels 18 are arranged in the second direction Y (vertical direction), for example. The number of pixels of the distance measurement pixels 20 in the first direction X (horizontal direction) may be any number. For example, each of the reference pixels 18 and the distance measurement pixels 20 outputs a voltage signal generated in response to arrival of a photon. Each of the reference pixels 18 and the distance measurement pixels 20 arranged in the first direction X inputs the voltage signal to the corresponding TDC 21. Each of the TDCs 21 converts the voltage signal received from the reference pixel 18 or the distance measurement pixel 20 into a time digital signal. While not illustrated in FIG. 2, the histogram generation unit 22 in FIG. 1 generates a histogram in reference to the time digital signal output from each of the TDCs 21. The signal processing unit 23 calculates a distance to the object 10 in reference to the generated histogram. While explained in the present description is an example where the number of the reference pixels 18 and the number of the distance measurement pixels 20 are equalized in the second direction Y, these numbers are not required to be the same number.

Each of the reference pixels 18 and the distance measurement pixels 20 in FIG. 2 has a pixel portion and an analog front-end portion (hereinafter referred to as an AFE portion). A voltage signal corresponding to a light pulse signal or a reflection light pulse signal is output from the AFE portion.

The light emission control unit 9 in the light emission unit 3 in FIG. 2 may include a register which stores information for adjustment of light emission timing and light emission waveforms. The driving circuit 7 individually adjusts light emission timing and light emission waveforms for each of the light emitting elements 5 in reference to the information stored in this register. Alternatively, the driving circuit 7 may collectively adjust the light emission timing and the light emission waveforms of all the light emitting elements 5 in reference to the respective items of information stored in the register.

While mainly presented in the present description is the example where a light pulse signal propagated through one optical waveguide 19 is received by one reference pixel 18, the pitch of the light emitting elements 5 is not necessarily equalized with the pitch of the reference pixels 18 and the pitch of the distance measurement pixels 20. Accordingly, a light pulse signal propagated through one optical waveguide 19 may be received by a plurality of reference pixels 18 in some cases.

### (Installation Location of Optical Waveguide 19)

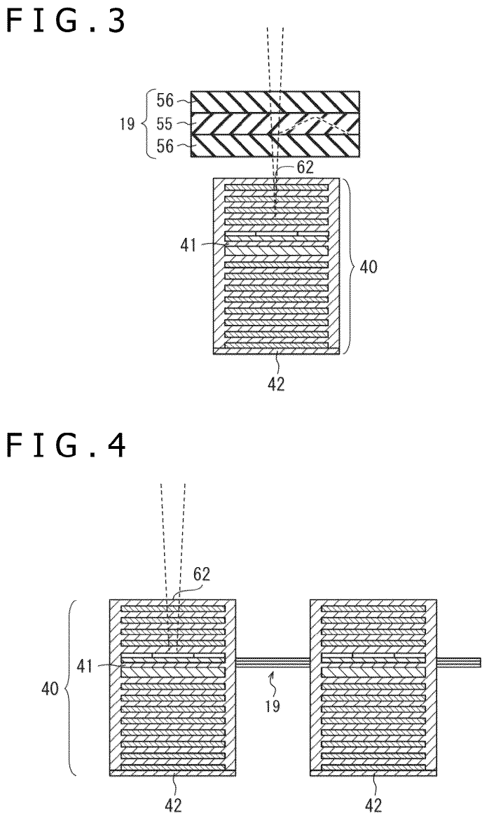

FIG. 3 is a cross-sectional diagram illustrating a positional relation between the light emitting element 5 and the optical waveguide 19. Each of the light emitting elements 5 includes a laminated film 40. The laminated film 40 which includes a first multilayer film reflection mirror, a first spacer layer, an active layer 41, a second spacer layer, a second multilayer film reflection mirror, and the like causes laser light generated in the active layer 41 to resonate between the first multilayer film reflection mirror and the second multilayer film reflection mirror to increase light intensity, and emits the laser light from one end surface side of the laminated film.

According to the example in FIG. 3, a light pulse signal generated at the active layer 41 is repeatedly reflected between the first multilayer film reflection mirror and the second multilayer film reflection mirror disposed on both the end surface sides of the laminated film 40, to increase light intensity, and is emitted from a light extraction portion 62 formed in the one end surface of the laminated film 40.

The optical waveguide 19 is disposed near the light extraction portion 62. A part of a light pulse signal emitted from the light extraction portion 62 is introduced into the optical waveguide 19, propagated through the optical waveguide 19, and received by the reference pixel 18.

For example, the optical waveguide 19 in FIG. 3 has such a structure where the circumference of a light transmission layer 55 is covered with a clad layer 56. The light transmission layer 55 and the clad layer 56 have different refractive indexes. Accordingly, the light pulse signal emitted from the light extraction portion 62 and introduced into the light transmission layer 55 can be propagated to the reference pixel 18 without light losses.

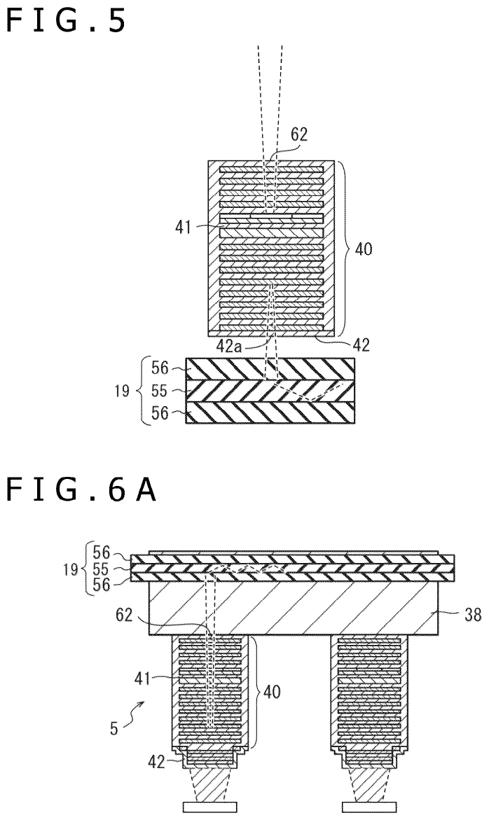

FIG. 4 is a cross-sectional diagram illustrating a first modification of FIG. 3. While the optical waveguide 19 in FIG. 3 is disposed on the one end side of the laminated film 40 of the light emitting element 5, the optical waveguide 19 in FIG. 4 is provided along the active layer 41 which is a part of the laminated film. A plurality of light emitting elements 5 are arranged apart from each other on the light emission unit 3. The active layers 41 disposed on the respective light emitting elements 5 have the same layer height. Accordingly, in the configuration where the optical waveguide 19 is disposed along the plurality of active layers 41, light pulse signals emitted from the respective light emitting elements 5 can be propagated through the same optical waveguide 19.

The optical waveguide 19 in FIG. 4 propagates some of light pulse signals generated in the active layers 41 and amplified. In the configuration where the optical waveguide 19 is disposed along the active layers 41, light pulse signals can be efficiently introduced into the optical waveguide 19 by utilization of a light confinement effect of the active layers 41.

Moreover, the optical waveguide 19 in FIG. 4 can be formed by use of the step of forming the laminated films. Accordingly, a separate step for forming the optical waveguide 19 is not required.

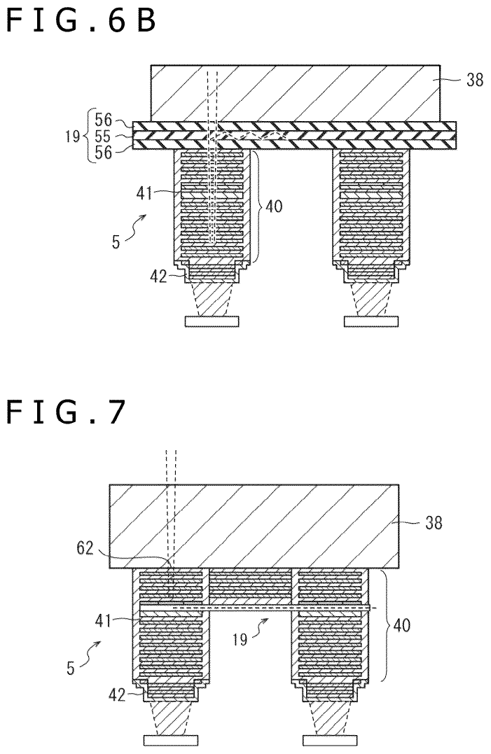

FIG. 5 is a cross-sectional diagram illustrating a second modification of FIG. 3. While illustrated in FIG. 3 is the example where the optical waveguide 19 is provided on the side of the light extraction portion 62 of the light emitting element 5, illustrated in FIG. 5 is such a configuration where the optical waveguide 19 is disposed on the side opposite to the light extraction portion 62 of the light emitting element 5. A layer including a material having high reflectance is provided on the end surface of the light emitting element 5 on the side opposite to the light extraction portion 62 so as to prevent leakage of light in a normal state. In FIG. 5, an opening 42a is formed in a part of the end surface on the side opposite to the light extraction portion 62 to emit a part of a light pulse signal through the opening 42a. The light pulse signal emitted from the opening 42a is allowed to be introduced into the optical waveguide 19 that is being disposed near the opening 42a.

As illustrated in FIGS. 3 to 5, the installation location of the optical waveguide 19 is set to any one of locations roughly divided into 1) a position near the light extraction portion 62 of the light emitting element 5, 2) a position near the active layer 41 of the light emitting element 5, and 3) a position on the side opposite to the light extraction portion 62 of the light emitting element 5.

### (Cross-Sectional Structure Near Optical Waveguide 19)

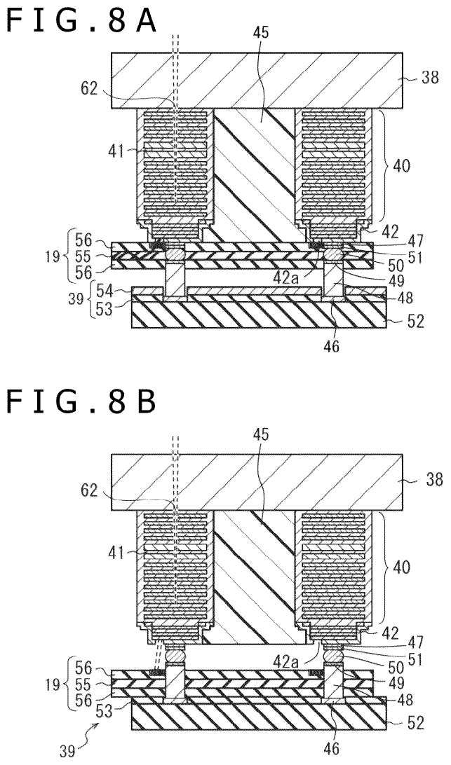

FIG. 6A is a cross-sectional diagram of a more specific illustration of the cross-sectional structure in FIG. 4 where the optical waveguide 19 is provided near the light extraction portion 62 of the light emitting element 5. FIG. 6A illustrates an example of a configuration including a VCSEL substrate 38 which includes the light emitting elements 5 each having a mesa structure. The light emitting elements 5 each having a mesa structure are disposed on the VCSEL substrate 38 at fixed intervals, and the optical waveguide 19 is disposed on the VCSEL substrate 38. Each of the light emitting elements 5 has the laminated film 40. A light pulse signal generated in the active layer 41 within the laminated film 40 is emitted from the light extraction portion 62 formed on the VCSEL substrate 38 side, transmitted through the VCSEL substrate 38, and introduced into the optical waveguide 19.

An unillustrated cathode electrode is disposed on the VCSEL substrate 38, while an anode electrode 42 is disposed at an end opposite to the light extraction portion 62 of each of the light emitting elements 5. Each of the anode electrodes 42 receives voltage supply from an unillustrated LDD substrate 39.

FIG. 6B is a cross-sectional diagram illustrating a modification of FIG. 6A. FIG. 6B is different from FIG. 6A in that the optical waveguide 19 is disposed at a different location. While the optical waveguide 19 in FIG. 6A is disposed on the surface of the VCSEL substrate 38 on the side opposite to the surface where the plurality of light emitting elements 5 are arranged, the optical waveguide 19 in FIG. 6B is disposed along the surface of the VCSEL substrate 38 on the side where the light emitting elements 5 are arranged. In other words, the optical waveguide 19 in FIG. 6B is disposed near the light extraction portion 62 of each of the light emitting elements 5.

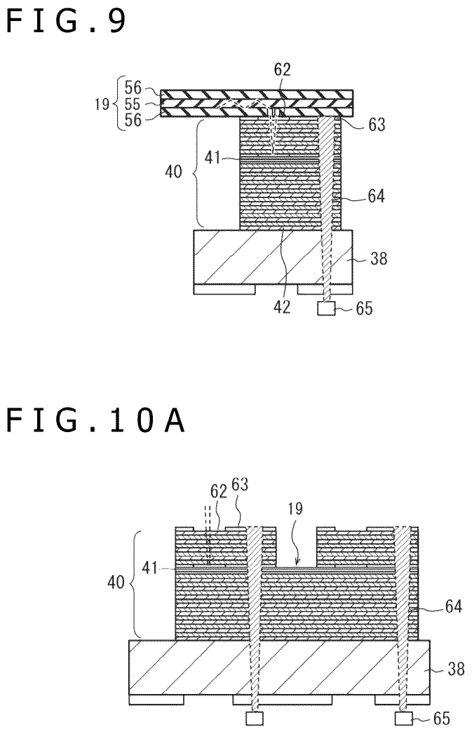

FIG. 7 is a cross-sectional diagram of a more specific illustration of the cross-sectional structure in FIG. 5 where the optical waveguide 19 is provided near the active layer 41 of the light emitting element 5. As illustrated in FIG. 7, the optical waveguide 19 is provided near the active layers 41 of the plurality of light emitting elements 5 on the VCSEL substrate 38. The optical waveguide 19 propagates a light pulse signal introduced from the active layer 41 included in any one of the plurality of light emitting elements 5.

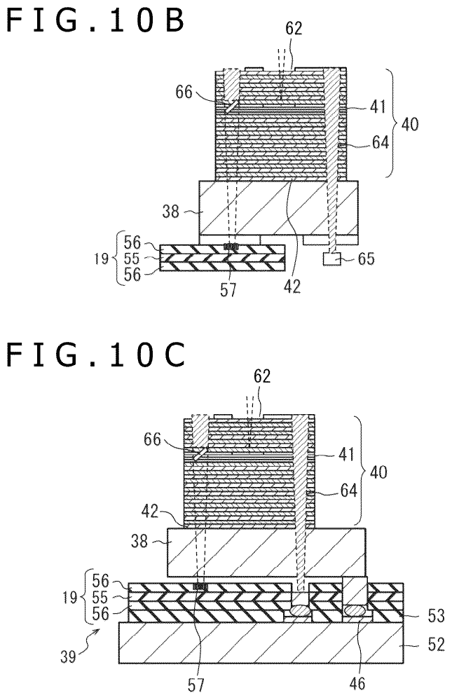

FIG. 8A is a cross-sectional diagram of a more specific illustration of the cross-sectional structure in FIG. 6 where the optical waveguide 19 is provided on the side opposite to the light extraction portion 62 of the light emitting element 5. According to the example in FIG. 8A, the opening 42a is formed at a part of the anode electrode 42 of each of the light emitting elements 5. A part of a light pulse signal repeatedly reflected on the laminated film 40 is emitted from the opening 42a. The optical waveguide 19 in FIG. 8A is disposed near the opening 42a, and the light pulse signal emitted from the opening 42a is introduced into the optical waveguide 19. Each of the anode electrodes 42 is bonded to the LDD substrate 39 via a bump or the like.

FIG. 8B is a cross-sectional diagram illustrating a modification of FIG. 8A. The optical waveguide 19 in FIG. 8B is disposed closer to the LDD substrate 39 than the optical waveguide 19 in FIG. 8A. In this configuration, the optical waveguide 19 can be formed by the step for manufacturing the LDD substrate 39. Accordingly, the manufacturing step can be simplified.

While each of FIGS. 6A, 6B, 7, 8A, and 8B illustrates the example where light is extracted from the rear surface side of the VCSEL substrate 38, light may be extracted from the front surface side of the VCSEL substrate 38. Each of the light emitting elements 5 configured to extract light from the front surface side of the VCSEL substrate 38 will hereinafter be referred to as a front-surface type VCSEL. Meanwhile, each of the light emitting elements 5 in FIGS. 6A, 6B, 7, 8A, and 8B can be referred to as a rear-surface type VCSEL.

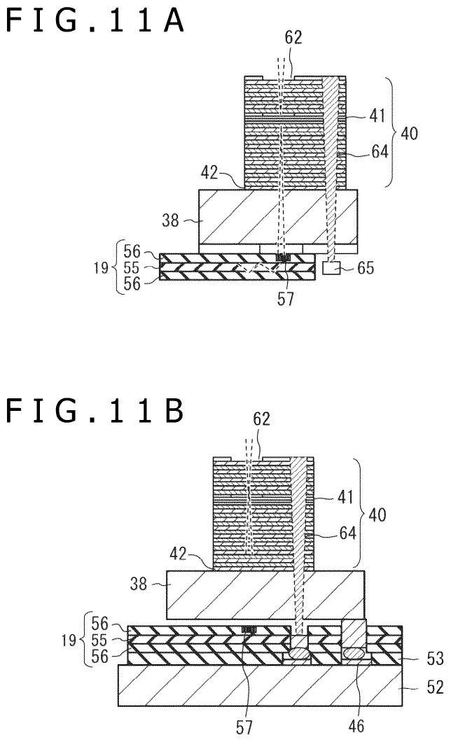

FIG. 9 is a cross-sectional diagram of the front-surface type VCSEL where the optical waveguide 19 is provided near the light extraction portion 62 of the light emitting element 5. The VCSEL substrate 38 in FIG. 9 is disposed on the side opposite to the side where the VCSEL substrate 38 is provided in FIG. 6A. The optical waveguide 19 is disposed near the light extraction portions 62 of the plurality of light emitting elements 5. An electrode layer 63 disposed near each of the light extraction portions 62 of the light emitting elements 5 is electrically connected to an electrode 65 disposed on the rear surface side of the VCSEL substrate 38 via a contact 64 penetrating the laminated film 40 and the VCSEL substrate 38.

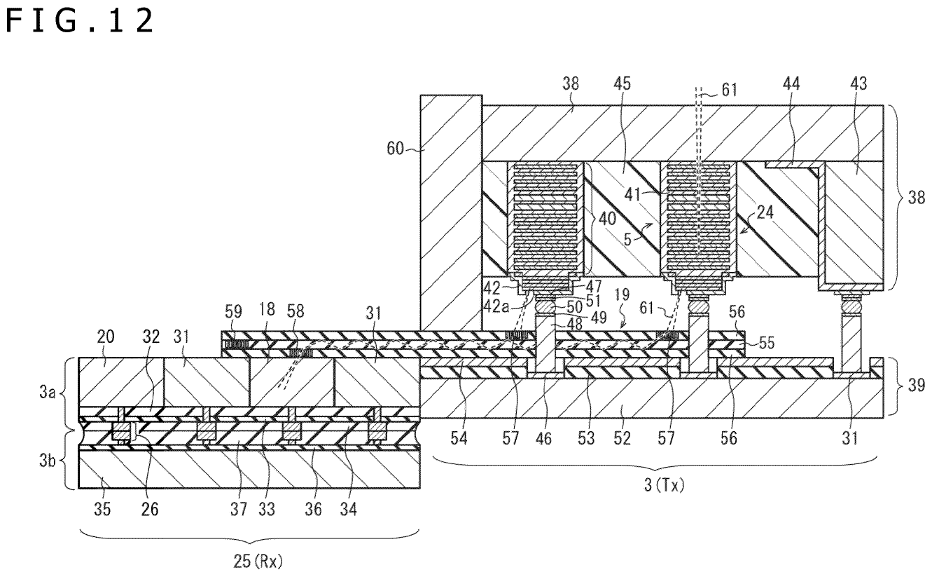

FIG. 10A is a cross-sectional diagram of the front-surface type VCSEL where the optical waveguide 19 is provided near the active layers 41 of the light emitting elements 5. The VCSEL substrate 38 in FIG. 10A is disposed on the side opposite to the side where the VCSEL substrate 38 is disposed in FIG. 7. Moreover, the electrode layer 63 disposed near each of the light extraction portions 62 of the light emitting elements 5 is electrically connected to an electrode on the rear surface side of the VCSEL substrate 38 via the contact 64 penetrating the laminated film 40 and the VCSEL substrate 38.

FIG. 10B is a cross-sectional diagram illustrating a first modification of FIG. 10A. FIG. 10B illustrates an example which guides, by a reflection member 66, a light pulse signal extracted from the active layer 41 in the lamination direction, and then introduces the light pulse signal into the optical waveguide 19 disposed on the rear surface side of the VCSEL substrate 38. FIG. 10B is similar to FIG. 10A in that light is extracted from the active layer 41, but is different from FIG. 10A in that the optical waveguide 19 is disposed not at a position near the active layer 41.

FIG. 10C is a cross-sectional diagram illustrating a second modification of FIG. 10A. FIG. 10C illustrates a cross-sectional structure similar to the cross-sectional structure in FIG. 10B, and indicates a more specific location of the optical waveguide 19. The optical waveguide 19 in FIG. 10C is disposed between the VCSEL substrate 38 and the LDD substrate 39. A light pulse signal extracted from the active layer 41 is guided in the lamination direction by the reflection member 66, transmitted through the laminated film 40 and the VCSEL substrate 38, and introduced into the optical waveguide 19.

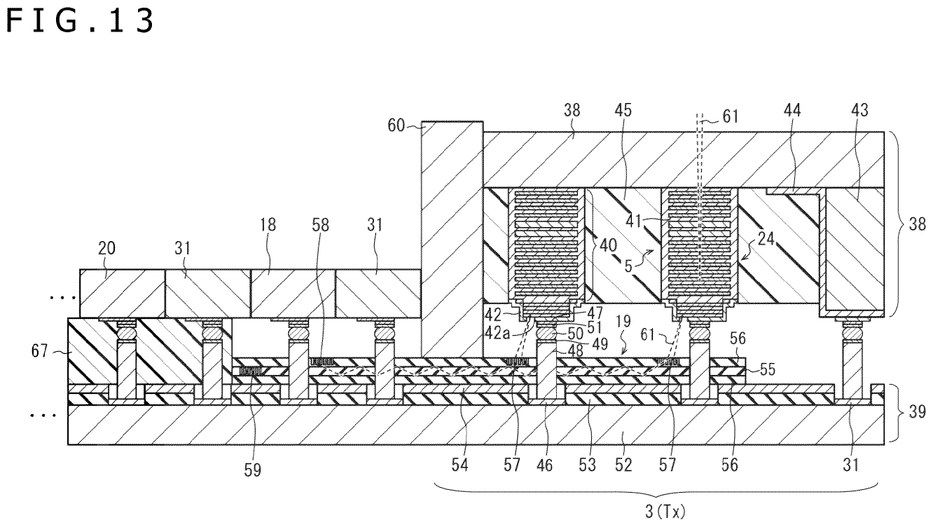

FIG. 11A is a cross-sectional diagram of the front-surface type VCSEL where the optical waveguide 19 is provided on the side opposite to the light extraction portion 62 of the light emitting element 5. The VCSEL substrate 38 in FIG. 11A is disposed on the side opposite to the side where the VCSEL substrate 38 is provided in FIG. 8A. A part of a light pulse signal repeatedly reflected within the laminated film 40 constituting the light emitting element 5 is emitted from the end surface of the laminated film 40 on the VCSEL substrate 38 side, transmitted through the VCSEL substrate 38, and introduced into the optical waveguide 19.

FIG. 11B is a cross-sectional diagram illustrating a modification of FIG. 11A. FIG. 11B illustrates a cross-sectional structure similar to the cross-sectional structure in FIG. 11A, and indicates a more specific location of the optical waveguide 19. The optical waveguide 19 in FIG. 11B is disposed between the VCSEL substrate 38 and the LDD substrate 39.

### (Detailed Structure Around Light Emission Unit 3 and Light Reception Unit 25)

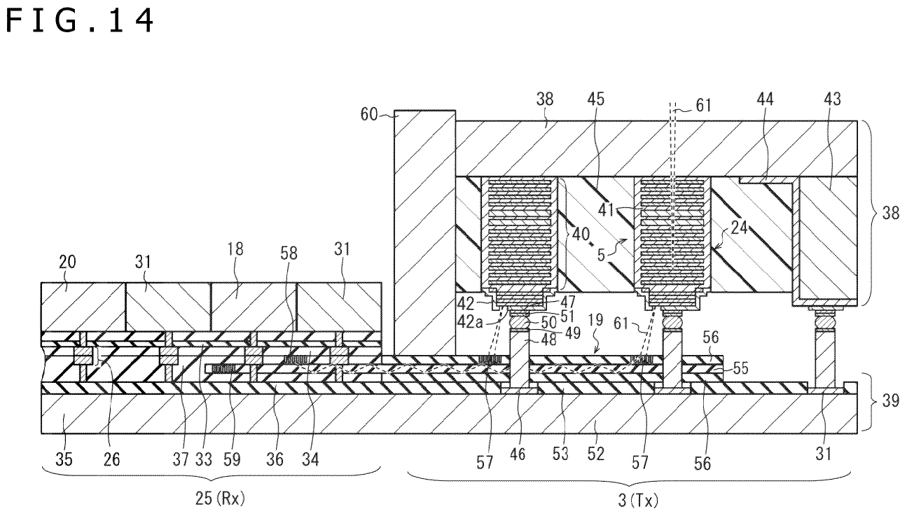

FIG. 12 is a cross-sectional diagram illustrating a structure around the light emission unit 3 and the light reception unit 25. According to the example in FIG. 12, a substrate 52 on which the light emission unit 3 is disposed and a substrate 35 on which the light reception unit 25 is disposed are separately provided. Note that the light emission unit 3 and the light reception unit 25 may be disposed on the same substrate.

The substrate 35 where the light reception unit 25 illustrated in FIG. 12 is disposed has a laminated structure, i.e., a structure including a first chip 3a and a second chip 3b bonded to each other by Cu—Cu bonding 26. The bonding mode between the first chip 3 and the second chip 3b is not limited to the Cu—Cu bonding 26, and may be bonding using a bump or the like.

As illustrated in FIG. 2, the first chip 3a includes the reference pixel 18 disposed close to the light emission unit 3 and the distance measurement pixel 20 disposed away from the light emission unit 3. A plurality of reference pixels 18 and a plurality of distance measurement pixels 20 are disposed in a depth direction with respect to the plane of FIG. 12, which is a direction corresponding to the second direction Y in FIG. 1.

In FIG. 12, a dummy pixel (DMY pixel) 31 is disposed between the reference pixel 18 and the light emission unit 3, and also between the reference pixel 18 and the distance measurement pixel 20. The dummy pixels 31 thus provided are not used for reception of light signals and reflection light signals from the light emitting elements 5, but for alignment between the reference pixel 18 and the distance measurement pixel 20 or for other purposes. The dummy pixels 31 may have any structure and size.

For example, each of the dummy pixels 31, the reference pixel 18, and the distance measurement pixel 20 on the first chip 3a has a photodiode which has a p-type Si (silicon) layer on an n-type Si (silicon) layer. An Si (silicon) layer 32, an SiN (silicon nitride) layer 33, and an Si (silicon) layer 34 are laminated on the lower surface side of each of the dummy pixel 31, the reference pixel 18, and the distance measurement pixel 20.

The second chip 3b includes a circuit for generating voltage to be applied to the anode electrodes and the cathode electrodes of the reference pixel 18 and the distance measurement pixel 20, a circuit for reading voltage signals from the anode electrodes, and others. For example, the second chip 3b has a structure including an SiN (silicon nitride) layer 36 and an SiO2 layer 37 each laminated on an Si (silicon) layer 35.

The light emission unit 3 has a laminated structure including the VCSEL substrate 38 where the VCSEL array 17 is disposed and the LDD (Laser Diode Driver) substrate 39 bonded to each other. The VCSEL substrate 38 is a substrate including a compound semiconductor such as GaAs. The VCSEL substrate 38 has a front surface on the side facing the LDD substrate 39, and emits laser light from the rear surface (the upper surface of the VCSEL substrate 38 in FIG. 12) side. A plurality of light emitting elements 5 each having a mesa structure are disposed at predetermined intervals on the VCSEL substrate 38. Each of the light emitting elements 5 includes the laminated film 40. The laminated film 40 which includes a first multilayer film reflection mirror, a first spacer layer, the active layer 41, a second spacer layer, a second multilayer film reflection mirror, and the like causes laser light generated in the active layer 41 to resonate between the first multilayer film reflection mirror and the second multilayer film reflection mirror, to increase light intensity, and emits the laser light from the rear surface of the substrate. Accordingly, the VCSEL array 17 in FIG. 12 is a back-illuminated-type VCSEL array.

The cathode electrodes 42 are disposed on the upper surfaces of the respective light emitting elements 5 as viewed from the VCSEL substrate 38 side. Similarly, an anode electrode 44 is disposed on an upper surface and a side surface of an undoped GaAs layer 43 disposed on the end side of the VCSEL array 17 as viewed from the VCSEL substrate 38. The anode electrode 44 is also disposed on the lowermost layer side of the laminated film 40 of each of the plurality of light emitting elements 5 as viewed from the VCSEL substrate 38 side. The cathode electrodes 42 and the anode electrode 44 in FIG. 12 may be arranged in opposite positions. While the anode electrode 44 is designated as a common electrode in FIG. 12, the cathode electrodes 42 may be designated as common electrodes. In this case, the anode electrodes 44 are provided at the respective mesa portions. Each circumference of the light emitting elements 5 is covered with a resin member 45, for example.

The LDD substrate 39 has a plurality of pads 46 through each of which a driving signal is supplied to the corresponding one of the plurality of light emitting elements 5 of the VCSEL array 17. The pads 46 of the LDD substrate 39 are joined to pads 47 of the corresponding cathode electrodes 42 of the VCSEL array 17.

For example, each of the pads 46 on the LDD substrate 39 is formed with use of a conductive material such as Al (aluminum). For example, each of the pads 47 on the cathode electrodes 42 is formed with use of a conductive material such as Co (cobalt). For example, a pillar 48 including Cu (copper) is disposed on each of the pads 46 on the LDD substrate 39. Conductive laminated films such as an Ni (nickel) layer 49, a solder layer 50, and an Au (gold) layer 51 are disposed between the upper surface of the pillar 48 and the pad 47.

The LDD substrate 39 has a laminated structure which has the base layer 52 including Si (silicon) or the like, an insulation layer 53 including SiN or the like that is laminated on the base layer 52, and a metal light shielding layer 54 including W (tungsten) or the like that is disposed on the insulation layer 53.

The LDD substrate 39 may have the driving circuit 7 in FIG. 1 for generating a driving signal. In this case, the LDD substrate 39 performs active driving. Alternatively, the LDD substrate 39 may supply to each of the pads 46 voltage corresponding to the driving signal which is generated by the driving circuit 7 provided separately from the light emission unit 3. In this case, the LDD substrate 39 performs passive driving.

The upper surface of the first chip 3a in the light emission unit 3 and the upper surface of the LDD substrate 39 are flush with each other. The optical waveguide 19 is disposed along these upper surfaces. The optical waveguide 19 has such a structure where the clad layer 56 such as SiO2 surrounds the circumference of the light transmission layer 55 through which light pulse signals are propagated.

The opening 42a is formed at a part of the cathode electrode 42 disposed on the upper surface of each of the light emitting elements 5. A light pulse signal emitted from each of the light emitting elements 5 is propagated toward the rear surface. However, a part of the light pulse signal is also propagated toward the front surface. The part of the light propagated to the front surface of each of the light emitting elements 5 is emitted through the opening 42a.

A grating coupler 57 is disposed on the optical waveguide 19 at a position facing the opening 42a of each of the light emitting elements 5. The grating coupler 57 is formed by removing a part of the clad layer 56 in a grating shape by lithography or other methods. The light pulse signal emitted from the opening 42a of each of the light emitting elements 5 is introduced into the optical waveguide 19 through the grating coupler 57 of the optical waveguide 19.

A grating coupler 58 is also disposed near the reference pixel 18 abutting on the optical waveguide 19. The light pulse signal propagated through the optical waveguide 19 passes through the grating coupler 58 thus provided, and enters the reference pixel 18. A Bragg mirror 59 is disposed at a light reception unit 25 side end of the optical waveguide 19 to confine the light pulse signal within the optical waveguide 19. In such a manner, the light pulse signal in the optical waveguide 19 is prevented from entering the distance measurement pixel 20.

A light shielding wall 60 is disposed in a boundary region between the light emission unit 3 and the light reception unit 25. The light shielding wall 60 is disposed on the optical waveguide 19.

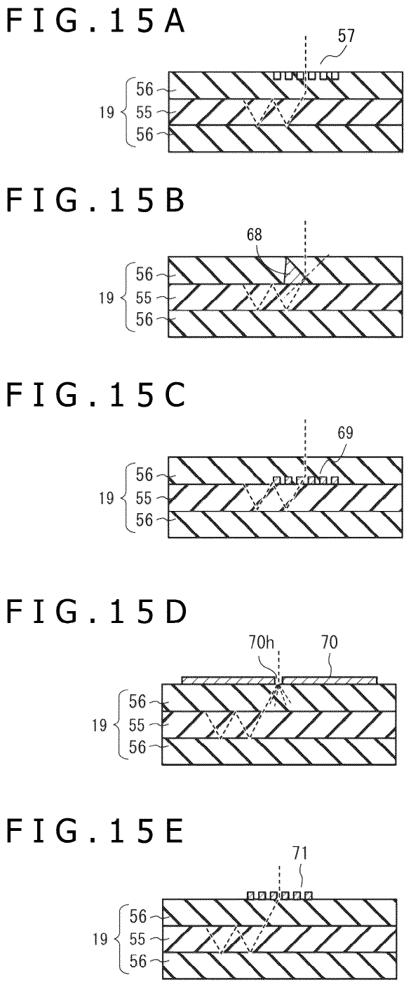

FIG. 13 is a cross-sectional diagram illustrating a first modification of FIG. 12. In FIG. 12, the substrate 35 on the light emission unit 3 side and the substrate 52 on the light reception unit 25 side are separately provided. In addition, the substrates 35 and 52 are disposed at different height positions. Meanwhile, the light emission unit 3 and the light reception unit 25 are disposed on the same LDD substrate 39 in FIG. 13. The optical waveguide 19 is disposed on the LDD substrate 39 via the insulation layer 53 including SiN and the metal light shielding layer 54 in FIG. 13. The optical waveguide 19 is integrally arranged from the light emission unit 3 to the vicinity of the reference pixel 18 in the light reception unit 25.

In FIG. 12, the reference pixel 18 and the distance measurement pixel 20 are disposed between the optical waveguide 19 and the substrate 35. In FIG. 13, on the other hand, the reference pixel 18 and the distance measurement pixel 20 are disposed above the optical waveguide 19. A light shielding resin layer 67 is disposed at the light reception unit 25 side end of the optical waveguide 19 so as to prevent entrance of a light pulse signal propagated through the optical waveguide 19 into the distance measurement pixel 20. The Bragg mirror 59 is disposed at the light emission unit 3 side end of the optical waveguide 19 in FIG. 13 as with the case of the optical waveguide 19 in FIG. 12.

While the reference pixel 18, the distance measurement pixel 20, and the dummy pixel 31 are connected to the substrate 35 by Cu—Cu bonding in FIG. 12, these components are bonded to the LDD substrate 39 via a conductive laminated film in FIG. 13. The light reception unit 25 is connected to the LDD substrate 39 similarly to the light emission unit 3. Accordingly, the light reception unit 25 is connected to the LDD substrate 39 by the same material as the material of the conductive laminated film connecting the light emission unit 3 and the LDD substrate 39. Other structures in FIG. 13 are similar to the corresponding structures in FIG. 12.

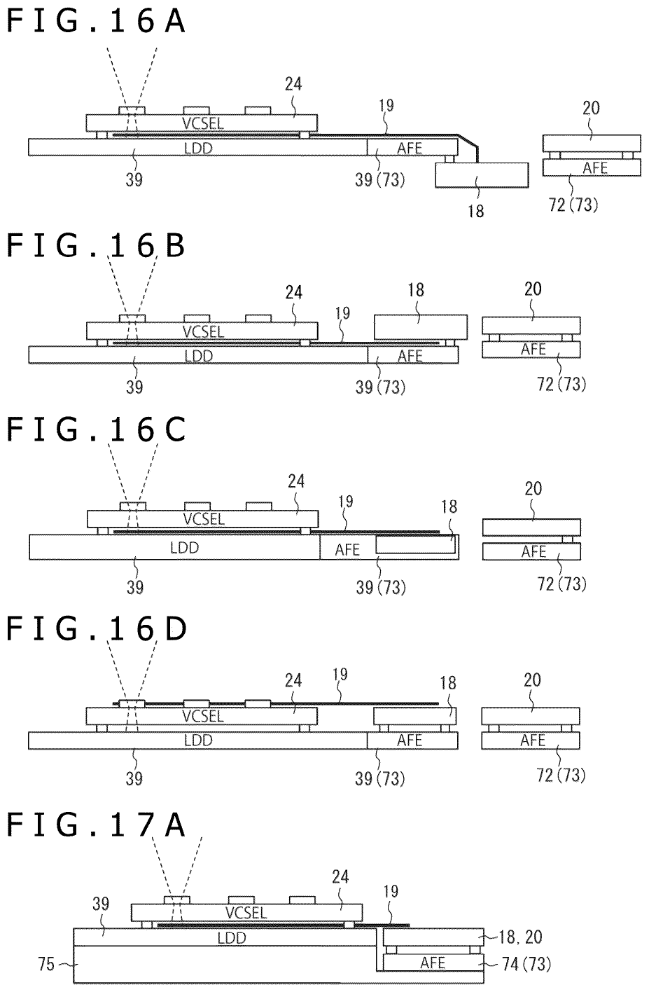

FIG. 14 is a cross-sectional diagram illustrating a second modification of FIG. 12. According to the second modification illustrated in FIG. 14, the light emission unit 3 and the light reception unit 25 are connected to the same LDD substrate 39 as in the case in FIG. 13. FIG. 14 is different from FIG. 13 in that the LDD substrate 39 and the light reception unit 25 are connected by Cu—Cu bonding. Moreover, an area around the light reception unit 25 side end of the optical waveguide 19 is covered by the insulation film 37 including SiO2 or the like, and the light shielding resin layer 67 in FIG. 13 is not provided. Note that the light shielding resin layer 67 may be disposed near the end of the optical waveguide 19. The Bragg mirror 59 is disposed at the light emission unit 3 side end of the optical waveguide 19 in FIG. 14 as in the cases of the optical waveguides 19 in FIGS. 12 and 13.

### Specific Example of Optical Coupling Means

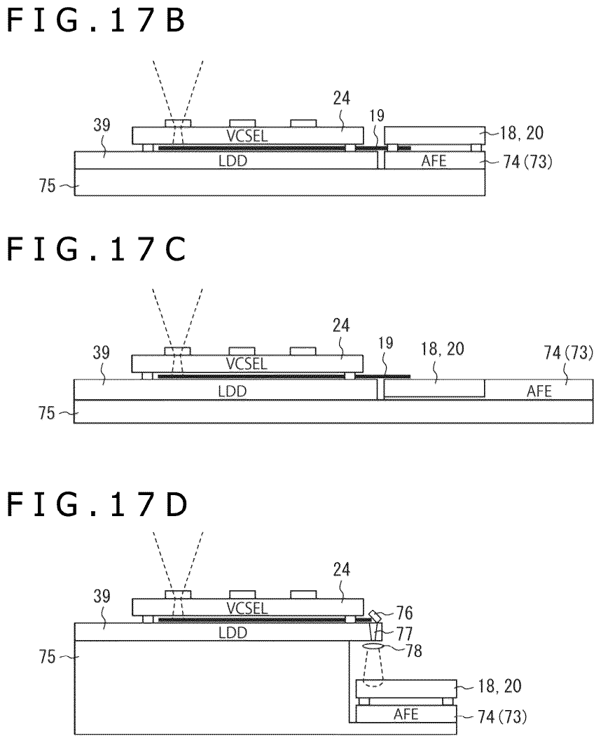

The grating coupler 57 described above is an example of optical coupling means for introducing a light pulse signal emitted from the light emitting element 5 into the optical waveguide 19. As illustrated in FIG. 15A, the grating coupler 57 is formed by processing a part of the clad layer 56 into a slit shape. The processing for forming the clad layer 56 into the slit shape is easily achieved by an existing semiconductor process such as etching.

FIG. 15B is a schematic cross-sectional diagram illustrating a first modification of the optical coupling means. The optical coupling means in FIG. 15B is a light refraction member 68 disposed at a part of the clad layer 56 of the optical waveguide 19. A light pulse signal emitted from the light emitting element 5 is refracted by the light refraction member 68, and introduced into the optical waveguide 19.

FIG. 15C is a schematic cross-sectional diagram illustrating a second modification of the optical coupling means. The optical coupling means in FIG. 15C includes a protruded and recessed structure 69 formed by micromachining a part of a surface of the clad layer 56 of the optical waveguide 19. When a light pulse signal from the light emitting element 5 is introduced into the protruded and recessed structure 69, the protruded and recessed structure 69 converts the traveling direction of the light pulse signal and guides the light pulse signal toward the optical waveguide 19.

FIG. 15D is a schematic cross-sectional diagram illustrating a third modification of the optical coupling means. According to the example in FIG. 15D, a metal layer 70 is disposed on the surface of the clad layer 56, and a hole 70h is formed in the metal layer 70. A light pulse signal from the light emitting element 5 is diffracted while passing through the hole 70h of the metal layer 70. As a result, diffracted light is introduced into the optical waveguide 19.

FIG. 15E is a schematic cross-sectional diagram illustrating a fourth modification of the optical coupling means. According to the example in FIG. 15E, metal nanoparticles 71 are disposed on the surface of the clad layer 56 to cause surface plasmon. This configuration can switch the traveling direction of a light pulse signal emitted from the light emitting element 5, and guide this light to the optical waveguide 19.

As described above, various methods are adoptable as the optical coupling means for introducing a light pulse signal emitted from the light emitting element 5 into the optical waveguide 19.

### (Substrate Carrying Light Emission Unit 3 and Substrate Carrying Light Reception Unit 25)

As illustrated in FIGS. 12 to 14, the light emission unit 3 and the light reception unit 25 may be disposed either on different substrates or on the same substrate. Moreover, each of the reference pixel 18 and the light emission unit 3 transmits and receives a light pulse signal via the optical waveguide 19. Accordingly, the reference pixel 18 and the light emission unit 3 may be disposed either on the same substrate or on different substrates.

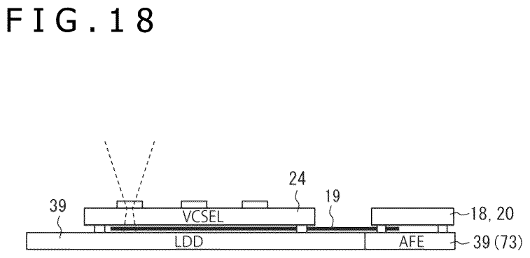

FIG. 16A is a schematic cross-sectional diagram illustrating an example where the reference pixel 18 is disposed on the LDD substrate 39 on which the light emission unit 3 is provided. According to the example in FIG. 16A, the VCSEL array 17 is disposed on a first main surface of the LDD substrate 39, while the reference pixel 18 is disposed on a second main surface of the LDD substrate 39 on the side opposite to the first main surface. The optical waveguide 19 is disposed on the first main surface of the LDD substrate 39 between the VCSEL array 17 and the reference pixel 18. A substrate 72 where the distance measurement pixel 20 is disposed is provided separately from the LDD substrate 39. An analog front-end portion (AFE portion) 73 for generating a voltage signal corresponding to a light reception signal is formed on the LDD substrate 39 and the substrate 72 where the distance measurement pixel 20 is disposed.

FIG. 16B is a schematic cross-sectional diagram illustrating a first modification of FIG. 16A. The reference pixel 18 in FIG. 16B is disposed on the first main surface which is the same surface as the surface where the VCSEL array 17 is provided. The optical waveguide 19 is disposed on the first main surface of the LDD substrate 39, and the VCSEL array 17 and the reference pixel 18 are disposed on the optical waveguide 19.

FIG. 16C is a schematic cross-sectional diagram illustrating a second modification of FIG. 16A. The reference pixel 18 in FIG. 16C is formed by processing of the LDD substrate 39. More specifically, the reference pixel 18 is formed by use of a semiconductor process for forming the AFE portion, a logic circuit, and the like provided on the LDD substrate 39. The optical waveguide 19 is disposed on the first main surface of the LDD substrate 39, the VCSEL array 17 is disposed on the optical waveguide 19, and the reference pixel 18 is disposed below the optical waveguide 19.

FIG. 16D is a schematic cross-sectional diagram illustrating a third modification of FIG. 16A. According to the example in FIG. 16D, the VCSEL array 17 and the reference pixel 18 are disposed on the LDD substrate 39, and the optical waveguide 19 is disposed on the VCSEL array 17 and the reference pixel 18. In each of the examples illustrated in FIGS. 16A to 16D, the substrate on which the distance measurement pixel 20 is disposed is provided separately from the LDD substrate 39 where the VCSEL array 17 and the reference pixel 18 are disposed. However, the reference pixel 18 and the distance measurement pixel 20 may be disposed on the same substrate.

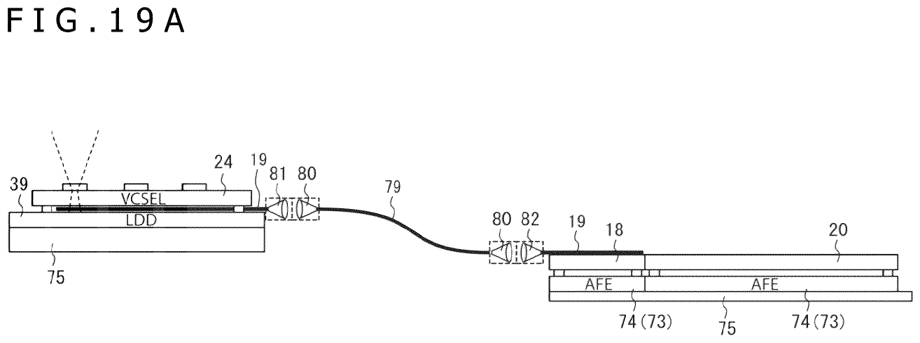

FIG. 17A is a schematic cross-sectional diagram illustrating an example where the reference pixel 18 is disposed on a substrate 74 different from the LDD substrate 39. As in the example in FIG. 12, the substrate 74 where the reference pixel 18 and the distance measurement pixel 20 are disposed is provided separately from the LDD substrate 39 where the VCSEL array 17 is disposed in the example of FIG. 17A. The substrates 39 and 74 thus provided are located at different height positions, and are both disposed on a support substrate 75. The optical waveguide 19 is disposed on the first main surface of the LDD substrate 39 and the upper surface of the reference pixel 18.

FIG. 17B is a schematic cross-sectional diagram illustrating a first modification of FIG. 17A. According to the example in FIG. 17B, the first main surface of the LDD substrate 39 where the light emitting element 5 is disposed, and the upper surface of the substrate where the reference pixel 18 and the distance measurement pixel 20 are disposed are flush with each other. The optical waveguide 19 is disposed on these surfaces.

FIG. 17C is a schematic cross-sectional diagram illustrating a second modification of FIG. 17A. According to the example in FIG. 17C, the reference pixel 18 and the distance measurement pixel 20 are formed on the substrate by use of a semiconductor process similar to the semiconductor process for forming the logic circuit and the AFE portion. Thereafter, the upper surfaces of the reference pixel 18 and the distance measurement pixel 20 are made flush with the upper surface of the LDD substrate 39, and the optical waveguide 19 is disposed on these surfaces.

FIG. 17D is a schematic cross-sectional diagram illustrating a third modification of FIG. 17A. FIG. 17D illustrates an example where a large step is produced between the LDD substrate 39 and the substrate 74 where the reference pixel 18 and the distance measurement pixel 20 are disposed. According to the example in FIG. 17D, a reflection mirror 76, a TSV (Through Silicon Via) 77, and an optical lens 78 are provided at an end of the LDD substrate 39. A light pulse signal emitted from an end of the optical waveguide 19 disposed on the LDD substrate 39 is introduced into the reference pixel 18 from an upper side, with the reflection mirror 76, the TSV 77, and the optical lens 78 being used for changing the traveling direction of the light pulse signal. According to the example illustrated in FIG. 17D, the substrate where the reference pixel 18 and the distance measurement pixel 20 are disposed is located below the LDD substrate 39. However, this substrate may be provided above the LDD substrate 39. In this case, it is only required to cause the light pulse signal to reflect upward by the reflection mirror 76.

While described with reference to FIGS. 16A to 16D and 17A to 17D have been the examples where the light emitting element 5, the reference pixel 18, and the distance measurement pixel 20 are disposed separately on at least two substrates, the light emitting element 5, the reference pixel 18, and the distance measurement pixel 20 may be disposed on the same substrate.

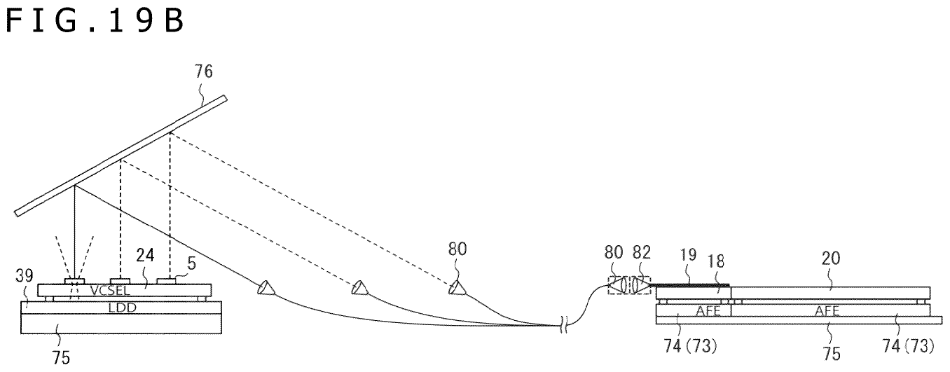

FIG. 18 is a schematic cross-sectional diagram illustrating an example where the light emitting element 5, the reference pixel 18, and the distance measurement pixel 20 are disposed on the LDD substrate 39. The AFE portion 73 is formed in a part of the LDD substrate 39 by a semiconductor process. The reference pixel 18 and the distance measurement pixel 20 are disposed on the AFE portion 73. Moreover, the VCSEL array 17 is disposed on the LDD substrate 39 in a region different from the AFE portion 73. Each of FIGS. 13 and 14 referred to above illustrates a more specific structure of the cross-sectional structure in FIG. 18.

### (Light Propagation Member Using Optical Fiber)

According to the examples described in the above embodiment, the optical waveguide 19 is disposed between the light emitting element 5 and the reference pixel 18. Yet, a light propagation member for propagating a light pulse signal is not limited to the optical waveguide 19. For example, the light propagation member may include an optical fiber and an optical connector.

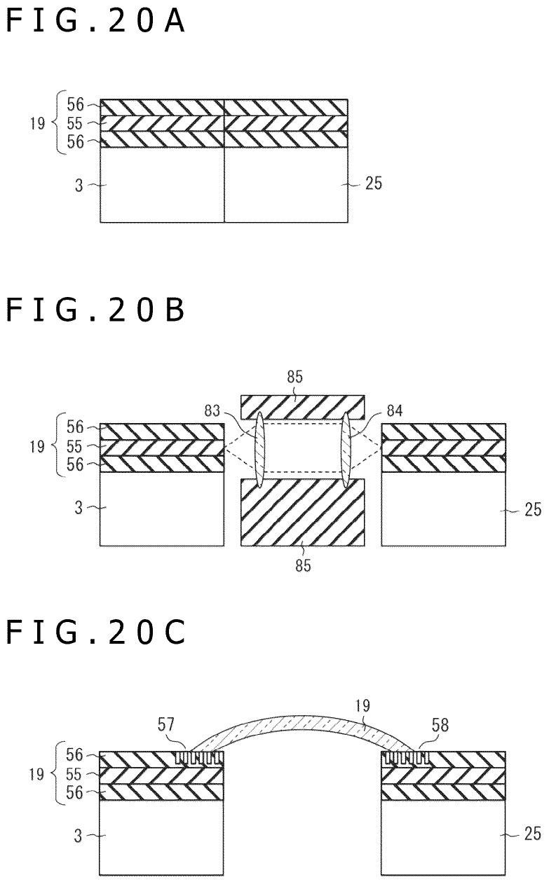

FIG. 19A is a diagram illustrating an example where a light propagation member including an optical fiber 79 and optical connectors 80 is disposed between the light emitting element 5 and the reference pixel 18. The optical connectors 80 are attached to both ends of the optical fiber 79. Moreover, individual optical connectors 81 and 82 are also attached to an end of the LDD substrate 39, and an end of the substrate where the reference pixel 18 and the distance measurement pixel 20 are disposed, respectively. A light pulse signal emitted from the light emitting element 5 can be introduced into the reference pixel 18 via the optical connectors 80 and the optical fiber 79 by connection between the optical connectors (80, 81) and between the optical connectors (80, 82).

The example in FIG. 19A will be described in more detail. The optical waveguide 19 is disposed on the LDD substrate 39, and the different optical waveguide 19 is also disposed on the reference pixel 18 separately from the optical fiber 79 and the optical connectors 80 described above. A light pulse signal emitted from the light emitting element 5 is propagated through the optical waveguide 19, passes through the optical connectors 81 and 80 at the end of the LDD substrate 39 and further through the optical fiber 79, and is received by the optical connectors 80 and 82 of the reference pixel 18 side substrate. Thereafter, the light pulse signal is propagated from the optical connector 80 to the optical waveguide 19, and is introduced into the reference pixel 18.

FIG. 19B is a cross-sectional diagram illustrating a modification of FIG. 19A. According to the example in FIG. 19B, the optical waveguide 19 need not be provided on the LDD substrate 39. Instead, the reflection mirror 76 is disposed above the VCSEL array 17. A light pulse signal emitted from each of the light emitting elements 5 in the VCSEL array 17 is reflected on the reflection mirror 76, introduced into the optical connector 80, propagated through the optical fiber 79, and introduced into the optical waveguide 19 on the upper surface of the reference pixel 18.

In each of the examples in FIGS. 19A and 19B, the light pulse signal is transmitted and received between the two substrates via the optical fiber 79. In this case, the two substrates can be provided at any positions, and hence the degree of freedom in determining the distance between the two substrates increases. Accordingly, the substrate 75 on the light emission unit 3 side and the substrate 75 on the light reception unit 25 side can be provided at any positions.

### (Light Pulse Signal Transmission and Reception Method Between Two Substrates)

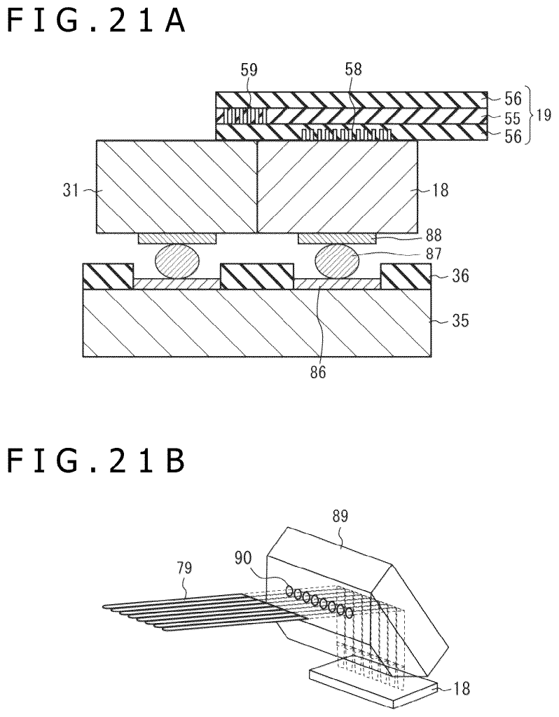

FIG. 20A is a diagram illustrating a first example of a light pulse signal transmission and reception method between the substrate of the light emission unit 3 and the substrate of the light reception unit 25. According to the example illustrated in FIG. 20A, the two substrates are disposed adjacent to each other, and the optical waveguide 19 is provided in such a manner as to extend over the two substrates as illustrated in FIGS. 12 to 14 and other figures, to directly transmit and receive a light pulse signal.

FIG. 20B is a diagram illustrating a second example of the light pulse signal transmission and reception method between the substrate of the light emission unit 3 and the substrate of the light reception unit 25. According to the example in FIG. 20B, an optical member is disposed between the light emission unit 3 side substrate and the light reception unit 25 side substrate. The optical member includes a first lens 83 for collimating a light pulse signal received from the light emission unit 3, a second lens 84 for collecting the light pulse signal transmitted through the first lens 83, and a lens holder 85 for holding the first lens 83 and the second lens 84. The light pulse signal emitted from an end of the optical waveguide 19 on the light emission unit 3 side substrate passes through the first lens 83 and the second lens 84, and is introduced into the optical waveguide 19 on the light reception unit 25 side substrate.

According to the example in FIG. 20B, the light pulse signal is transmitted and received between the two substrates by an optical action. Accordingly, transfer of the light pulse signal is achievable regardless of the distance between the two substrates.

FIG. 20C is a diagram illustrating a third example of the light pulse signal transmission and reception method between the substrate of the light emission unit 3 and the substrate of the light reception unit 25. FIG. 20C is similar to FIG. 20A in that a light pulse signal is transmitted and received by use of the optical waveguide 19, but is different from FIG. 20A in that the two substrates are disposed apart from each other. The optical waveguide 19 disposed between the two substrates is provided separately from the optical waveguide 19 disposed on the light emission unit 3 side substrate and the optical waveguide 19 disposed on the light reception unit 25 side substrate. For example, the grating coupler 57 is provided on the optical waveguide 19 disposed on the light emission unit 3 side substrate. Similarly, for example, the grating coupler 57 is also provided on the optical waveguide 19 disposed on the light reception unit 25 side substrate. A light pulse signal is introduced or released by the grating couplers 57 thus provided.

Note that the optical fiber 79 may be provided in place of the optical waveguide 19 disposed between the two substrates.

(Light Guidance from Light Propagation Member to Reference Image)

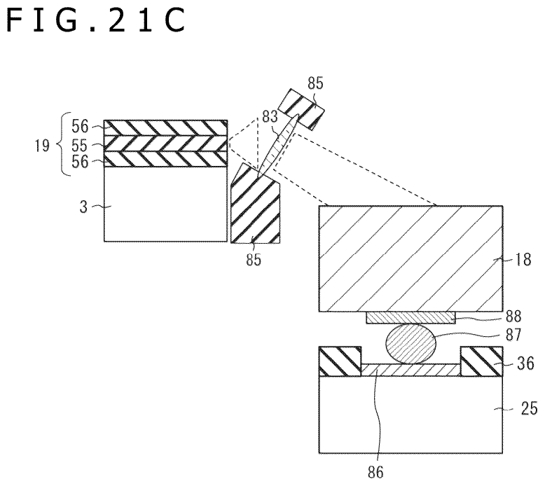

FIG. 21A is a diagram illustrating an example which adopts the grating coupler 57 as means for introducing a light pulse signal propagated through a light propagation member such as the optical waveguide 19 into the reference pixel 18. As described above, the grating coupler 57 can easily be manufactured by a semiconductor process, and produces smaller losses of a light pulse signal. Accordingly, efficient introduction of a light pulse signal from the light propagation member into the reference pixel 18 is achievable.

FIG. 21B is a schematic perspective diagram illustrating a first modification of FIG. 21A. FIG. 21B illustrates an example which adopts optical means instead of the grating coupler 58 to introduce a light pulse signal from the light propagation member into the reference pixel 18. According to the first modification of FIG. 21B, a reflection mirror 89 is provided to reflect a light pulse signal emitted from the light propagation member such as the optical waveguide 19 and the optical fiber 79. The light pulse signal reflected on the reflection mirror 89 is introduced into a light reception surface of the reference pixel 18.

FIG. 21C is a schematic cross-sectional diagram illustrating a second modification of FIG. 21A. Similarly to FIG. 21B, FIG. 21C illustrates an example which adopts optical means instead of the grating coupler 58 to introduce a light pulse signal from the light propagation member into the reference pixel 18. According to the second modification in FIG. 21C, a collimating lens 83 for collimating a light pulse signal emitted from the light propagation member such as the optical waveguide 19 on the light emission unit 3 side and a lens holder holding the collimating lens 83 are provided. The light pulse signal collimated by the collimating lens 83 is introduced into the light reception surface of the reference pixel 18.

### (Light Receiving Element 30 Constituting Reference Pixel 18)

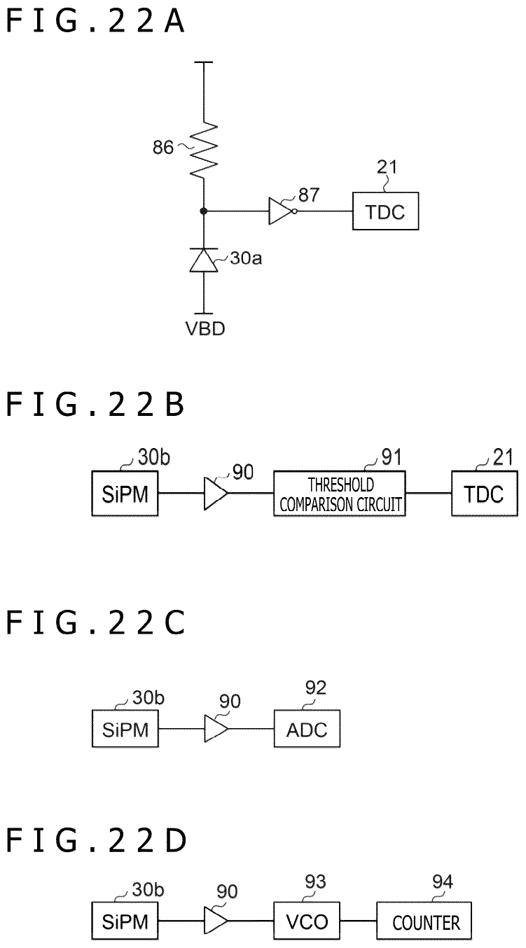

FIG. 22A is a diagram illustrating an example which adopts an SPAD 30a as the light receiving element 30 constituting the reference pixel 18. FIG. 22A is a diagram illustrating a circuit configuration of the SPAD 30a. As illustrated in FIG. 22A, an anode of the SPAD 30a is connected to a breakdown voltage VBD node. A resistance element 86 is connected to and between a cathode of the SPAD 30a and a power source voltage node. Moreover, an inverter 87 is connected to the cathode of the SPAD 30a. Cathode voltage of the SPAD 30a has a voltage level corresponding to arrival of a photon. A voltage signal as inverted cathode voltage of the SPAD 30a is output from the inverter 87, and input to the TDC 21.

Each of FIGS. 22B, 22C, and 22D is a diagram illustrating an example which adopts an SiPM (Silicon Photomultiplier) 30b as the reference pixel 18. The SiPM 30b includes a plurality of SPADs 30a. For performing distance measurement by a dToF (direct Time of Flight) method using the SiPM 30b, a transimpedance amplifier (hereinafter referred to as a TIA) 90, a threshold comparison circuit 91, and the TDC 21 are provided in a stage following the SiPM 30b as illustrated in FIG. 22B. For performing iToF (indirect Time of Flight) using the SiPM 30b, the TIA 90 and an ADC 92 are provided in a stage following the SiPM 30b as illustrated in FIG. 22C. For performing photon counting using the SiPM 30b, the TIA 90, a VCO (Voltage Controlled Oscillator) 93, and a counter 94 are provided in a stage following the SiPM 30b as illustrated in FIG. 22D.

As apparent from above, the configuration of the light receiving element 30 constituting the reference pixel 18 is variable depending on which action the optical detection device 1 desires to perform in dToF, iToF, and photon counting.

### (Optical Switch)

Described in the above embodiment has been the example which selects only one of the plurality of light emitting elements 5 each capable of introducing a light pulse signal into the corresponding optical waveguide 19 as the light emitting element 5 for emitting light, and sequentially switches the light emitting element 5 for emitting a light pulse signal. In this case, control is needed to achieve sequential switching of light emission between the plurality of light emitting elements 5. Meanwhile, according to such a configuration which includes optical switches 27 between the plurality of light emitting elements 5 and the optical waveguide 19 and sequentially switches on-off of the optical switches 27, light pulse signals from the respective light emitting elements 5 can be sequentially propagated via the optical waveguide 19 even if the plurality of light emitting elements 5 emit the light pulse signals at the same timing.

The optical switches 27 may have any specific form. For example, the optical switches 27 may be optical gate switches, Mach-Zehnder interferometers, directional couplers, or switches using other systems.

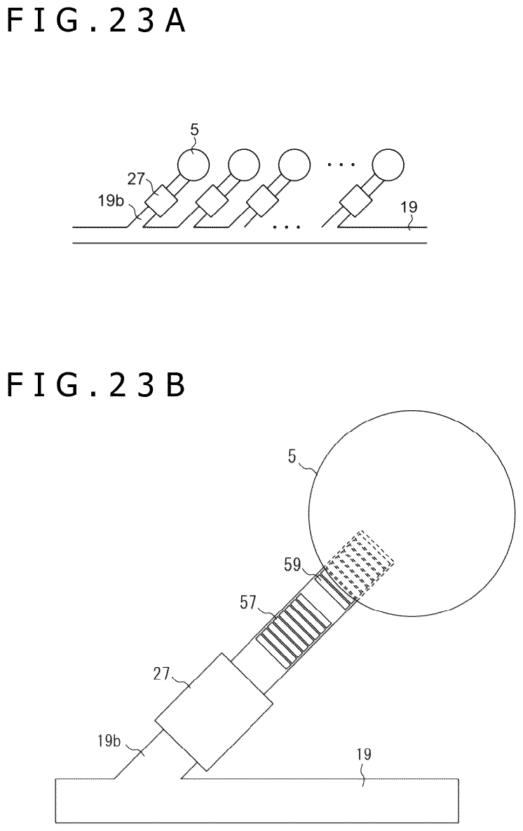

FIG. 23A is a plan diagram schematically illustrating the optical switches 27 disposed between the respective light emitting elements 5 and the corresponding optical waveguide 19. In an off-state of the optical switches 27, light pulse signals are not propagatable through the optical waveguide 19 even when the respective light emitting elements 5 emit light pulse signals. In other words, the optical switches 27 are capable of propagating a light pulse signal emitted from any one of the light emitting elements 5.

FIG. 23B is a plan diagram illustrating an enlarged structure around the optical switch. Each of the light emitting elements 5 disposed near the optical waveguide 19 is connected to a corresponding branch line 19b extending from a main line of the optical waveguide 19. Each of the branch lines 19b includes the optical switch 27, the grating coupler 57, and the Bragg mirror 59.

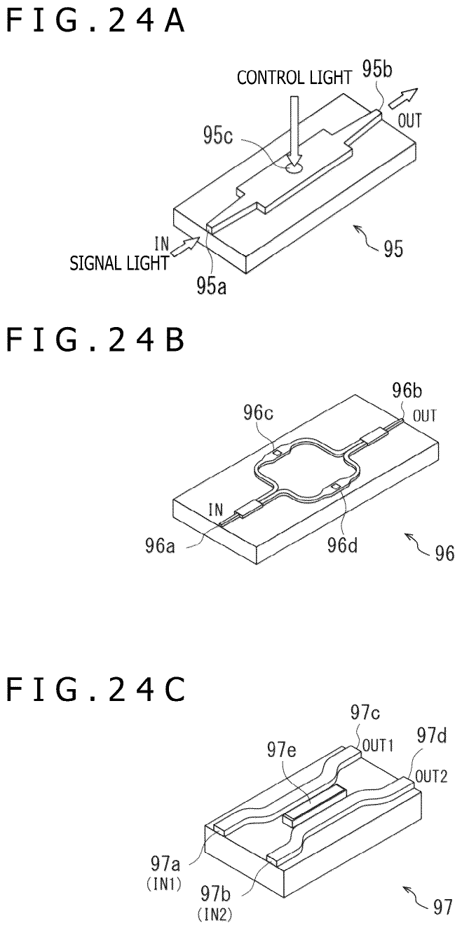

FIG. 24A is a perspective diagram of an optical gate switch 95 which is a first example of the optical switch. The optical gate switch 95 includes a first introduction portion 95a for introducing a light pulse signal, an emission portion 95b for emitting the light pulse signal, and a second introduction portion 95c for introducing control light. Control light introduced into the second introduction portion 95c can switch whether or not to emit from the emission portion 95b the light pulse signal introduced into the first introduction portion 95a.

FIG. 24B is a perspective diagram of a Mach-Zehnder interference type optical switch 96 which is a second example of the optical switch. The optical switch 96 in FIG. 24B branches a light pulse signal introduced into an introduction portion into two lines to change the phase of the light pulse signal within the branched optical waveguide 19 in each of the lines. The two light pulse signals transmitted through the two branched optical waveguides 19 are joined, and then emitted from an emission portion. Whether or not to emit from the emission portion the light pulse signal introduced into the introduction portion can be switched by switching the manner of the phase change.

FIG. 24C is a perspective diagram of a directional coupling type optical switch 97 which is a third example of the optical switch. The optical switch 92 in FIG. 24C includes a first introduction portion (IN1) 97a, a second introduction portion (IN2) 97b, a first emission portion (OUT1) 97c, and a second emission portion (OUT2) 97d. The two optical waveguides 19 connected to the first introduction portion (IN1) 97a and the second introduction portion (IN2) 97b are temporarily joined, and then divided into two parts. From which of the first emission portion (OUT1) 97c and the second emission portion (OUT2) 97d each of a first light pulse signal introduced into the first introduction portion (IN1) 97a and a second light pulse signal introduced into the second introduction portion (IN2) 97b is to be emitted can be switched according to a phase change of a phase change material at the junction portion of the two optical waveguides 19.

According to the present embodiment, as apparent from above, light signals emitted from the plurality of light emitting elements 5 are received by the plurality of reference pixels 18 via a plurality of light propagation members (e.g., optical waveguides 19). Accordingly, time differences in light emission timing between the plurality of light emitting elements 5 are accurately detectable. As a result, distance measurement is achievable in consideration of time differences in light emission timing between the plurality of light emitting elements 5 by use of the detected time differences, and distance measurement accuracy therefore improves.

Moreover, light emission waveforms of light pulse signals emitted from the plurality of light emitting elements 5 are detectable using the plurality of optical waveguides 19 and the plurality of reference pixels 18. Accordingly, light emission waveforms of the plurality of light emitting elements 5 are correctable according to the detected light emission waveforms of the light pulse signals.

The optical waveguide 19 described above can be disposed on the substrate for supporting the plurality of light emitting elements 5, or the LDD substrate 39 for supplying voltage to the plurality of light emitting elements 5. Accordingly, the optical waveguide 19 can be formed by a semiconductor process for processing the substrates.

Optical coupling means such as a grating coupler provided on the optical waveguide 19 allows efficient introduction of light pulse signals into the optical waveguide 19 from the plurality of light emitting elements 5. Further, in a case where the substrate on which the light emission unit 3 is disposed is located apart from the substrate on which the light reception unit 25 is disposed, propagation of light pulse signals from the light emission unit 3 to the reference pixels 18 is achievable by use of a light propagation member such as the optical fiber 79.

In addition, for disposing the light emission unit 3 and the light reception unit 25 on the same substrate, transfer of light pulse signals from the light emitting elements 5 to the reference pixels 18 is easily achievable by providing the optical waveguide 19 on this substrate.

### Application Example

The technology according to the present disclosure is applicable to various products. For example, the technology according to the present disclosure may be practiced in the form of a device mounted on a mobile body of any type selected from cars, electric cars, hybrid electric cars, motorcycles, bicycles, personal mobilities, airplanes, drones, vessels, robots, construction machines, agricultural machines (tractors), and others.

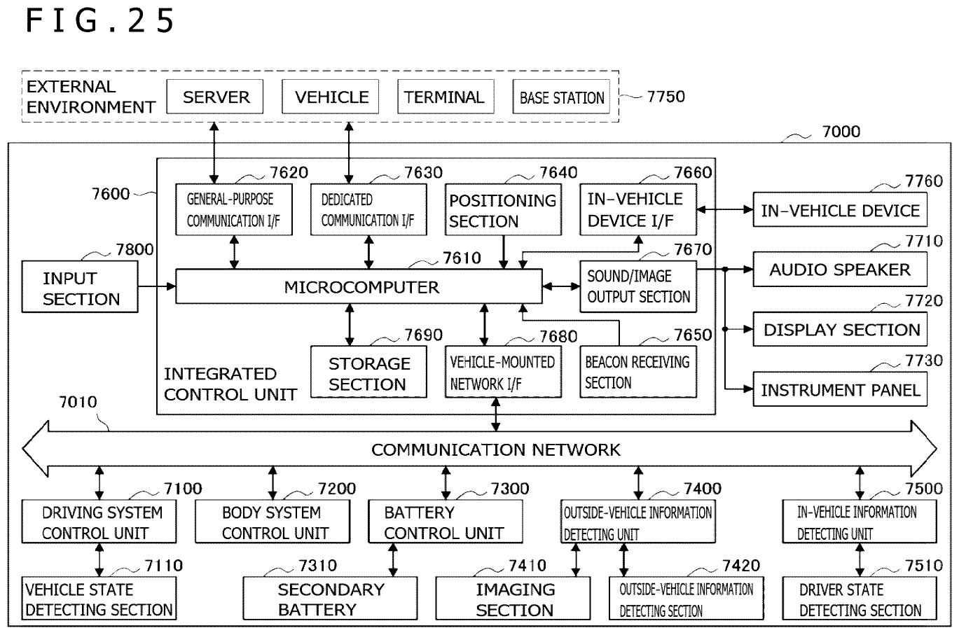

FIG. 25 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 25, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 25 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

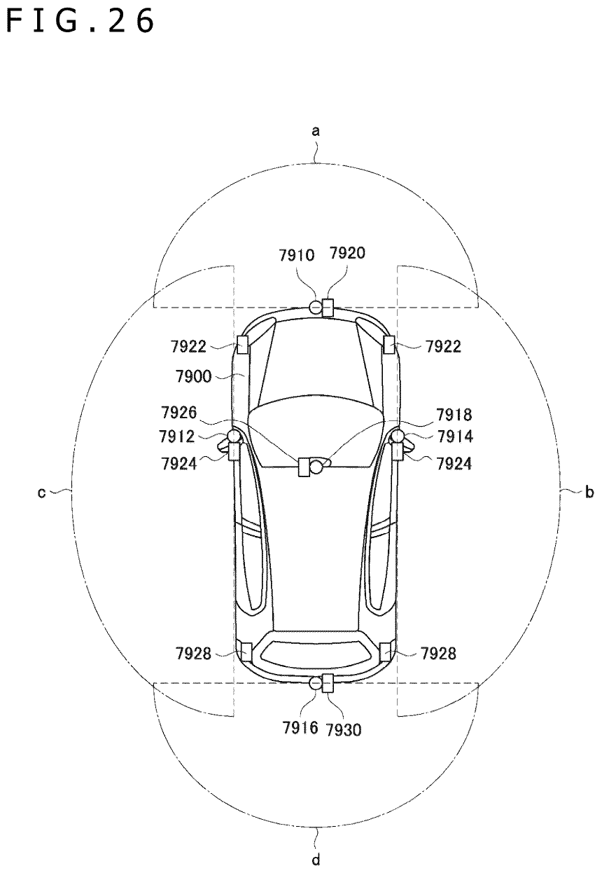

FIG. 26 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 25, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 25, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 25 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for achieving the respective functions of the optical detection device 1 according to the present embodiment described with reference to FIG. 1 and other figures may be implemented in any control unit or the like. Moreover, a computer-readable recording medium storing such a computer program may be provided. For example, this recording medium is a magnetic disk, an optical disk, a magneto-optical disk, a flash memory, or the like. Furthermore, the computer program described above may be distributed not using the recording medium but via a network, for example.

According to the vehicle control system 7000 described above, the optical detection device 1 described with reference to FIG. 1 and other figures in the present embodiment is applicable to the integrated control unit 7600 in the application example illustrated in FIG. 25.

Moreover, at least some of the constituent elements of the optical detection device 1 described with reference to FIG. 1 and other figures may be provided by a module (e.g., an integrated circuit module constituted by one die) for the integrated control unit 7600 illustrated in FIG. 25. Alternatively, the optical detection device 1 described with reference to FIG. 1 may be provided by a plurality of control units included in the vehicle control system 700 illustrated in FIG. 25.

Note that the present disclosure can take the following configurations.

(1)

An optical detection device including:
a plurality of light emitting elements each of which emits a first light pulse signal;
a plurality of light propagation members that propagate the first light pulse signals emitted from the plurality of light emitting elements;
a plurality of first light receiving elements that receive the first light pulse signals propagated through the plurality of light propagation members;
a plurality of second light receiving elements that receive reflection light pulse signals obtained by the first light pulse signals emitted from the plurality of light emitting elements being reflected on an object; and
a plurality of light guide members that guide the first light pulse signals emitted from the plurality of light emitting elements to the plurality of light propagation members.
   (2)

The optical detection device according to (1), in which
each of the plurality of light emitting elements includes a laminate that includes an active layer and a light extraction portion, and
a part of the first light pulse signal emitted from the corresponding light extraction portion is introduced into each of the plurality of light propagation members.
   (3)

The optical detection device according to (2), including:
a first substrate that supports a plurality of the laminates and transmits the first light pulse signal emitted from each of the light extraction portions; and
a plurality of electrodes disposed at ends of the plurality of laminates on a side opposite to the light extraction portions, in which
the plurality of light propagation members are disposed along the first substrate.
   (4)

The optical detection device according to (2), including:
a first substrate that is disposed on a side opposite to the light extraction portions of a plurality of the laminates and supports the plurality of laminates; and
a plurality of electrodes that are disposed on the first substrate and supply voltage to the plurality of laminates, in which
the plurality of light propagation members are disposed along the first substrate.
   (5)

The optical detection device according to (1), in which
each of the plurality of light emitting elements includes a laminate that includes an active layer and a light extraction portion, and
each of the plurality of light propagation members propagates a part of the first light pulse signal emitted from the corresponding active layer.
   (6)

The optical detection device according to (5), including:
a first substrate that supports the plurality of laminates and transmits the first light pulse signal emitted from each of the light extraction portions; and
a plurality of electrodes disposed at ends of the plurality of laminates on a side opposite to the light extraction portions, in which
the plurality of light propagation members are disposed along a plurality of the active layers.
   (7)

The optical detection device according to (5), including:
a first substrate that is disposed on a side opposite to the light extraction portions of a plurality of the laminates and supports the plurality of laminates; and
a plurality of electrodes disposed on the first substrate, in which
the plurality of light propagation members are disposed along a plurality of the active layers.
   (8)

The optical detection device according to (1), in which
each of the plurality of light emitting elements includes a laminate that includes an active layer and a light extraction portion, and a light reflection member disposed on a side opposite to the light extraction portion with the active layer interposed between the light reflection member and the light extraction portion, and
each of the plurality of light propagation members propagates the first light pulse signal emitted from an opening formed at a part of the corresponding light reflection member.
   (9)

The optical detection device according to (8), including:
a first substrate that supports the plurality of laminates and transmits the first light pulse signal emitted from each of the light extraction portions;
a plurality of electrodes disposed at ends of the plurality of laminates on a side opposite to the light extraction portions; and
a second substrate that generates voltage to be supplied to the plurality of electrodes, in which
the plurality of light propagation members are disposed on the second substrate.
   (10)

The optical detection device according to (8), including:
a first substrate that is disposed on a side opposite to the light extraction portions of a plurality of the laminates and supports the plurality of laminates;
a plurality of electrodes disposed on the first substrate; and
a second substrate that generates voltage to be supplied to the plurality of electrodes, in which
the plurality of light propagation members are disposed on the second substrate.
   (11)

The optical detection device according to any one of (1) through (10), including:
a light emission substrate where the plurality of light emitting elements are disposed; and
a light reception substrate where the plurality of first light receiving elements and the plurality of second light receiving elements are disposed, in which
each of the plurality of light propagation members is disposed in such a manner as to extend over the light emission substrate and the light reception substrate.
   (12)

The optical detection device according to any one of (1) through (10), including:
a substrate where the plurality of light emitting elements, the plurality of first light receiving elements, and the plurality of second light receiving elements are disposed, in which
the plurality of light propagation members are disposed on the substrate.
   (13)

The optical detection device according to any one of (1) through (10), including:
a light emission substrate where the plurality of light emitting elements and the plurality of first light receiving elements are disposed; and
a light reception substrate where the plurality of second light receiving elements are disposed, in which
each of the plurality of light propagation members is disposed in such a manner as to extend over the light emission substrate and the light reception substrate.
   (14)

The optical detection device according to any one of (11) through (13), in which
the plurality of first light receiving elements are disposed closer to the plurality of light emitting elements than the plurality of second light receiving elements, and
the plurality of light propagation members are disposed from a region containing the plurality of light emitting elements to a region containing the plurality of first light receiving elements.
   (15)

The optical detection device according to any one of (1) through (14), including:
a light shielding member that shields light to prevent entrance of the first light pulse signals propagated through the plurality of light propagation members into the plurality of second light receiving elements.
   (16)

The optical detection device according to any one of (1) through (15), in which each of the plurality of light guide members has a grating coupler.

(17)

The optical detection device according to any one of (1) through (16), in which each of the plurality of light guide members switches the first light pulse signals emitted from two or more of the light emitting elements to propagate the first light pulse signals.

(18)

The optical detection device according to (17), including:
two or more optical switches each of which is connected to the corresponding one of the plurality of light guide members, in which
the first light pulse signals emitted from the two or more light emitting elements are sequentially introduced into the corresponding light guide member by sequentially turning on the two or more optical switches one by one.
   (19)

The optical detection device according to any one of (1) through (18), in which each of the first light receiving elements includes an SPAD (Single Photon Avalanche photodiode), an SiPM (Silicon Photomultiplier), an iToF (indirect Time of Flight) sensor, or a photon count sensor.

(20)

The optical detection device according to any one of (1) through (17), in which each of the light propagation members has an optical waveguide, or an optical fiber and an optical connector.

Modes of the present disclosure are not limited to the individual embodiments described above and include various modifications arrived at by those skilled in the art. In addition, advantageous effects of the present disclosure are not limited to the details of the advantageous effects described above. In other words, various additions, changes, and partial deletions may be made without departing from the scope of the conceptual idea and spirit of the present disclosure derived from the contents specified in the claims and equivalents thereof.

### REFERENCE SIGNS LIST

1: Optical detection device
2: Distance measuring system
3: Light emission unit
3a: First chip
3b: Second chip
4: Overall control unit
5: Light emitting element
6: Light emission source
7: Driving circuit
8: Clock generation unit
9: Light emission control unit
10: Object
11: Pixel array unit
11a: Reference pixel array unit
11b: Distance measurement pixel array unit
12: Distance measurement processing unit
13: Control unit
14: Clock generation unit
15: Light emission timing control unit
16: Driving circuit
17: VCSEL array
18: Reference pixel
19: Optical waveguide
19b: Branch line
20: Distance measurement pixel
21: Time digital converter (TDC)
22: Histogram generation unit
23: Signal processing unit
23a: Distance measuring unit
24: Distance measurement control unit
25: Light reception unit
26: Cu—Cu bonding
27: Optical switch
28: Output buffer
30: Light receiving element
31: Dummy pixel
32: (Silicon) Layer
33: (Silicon nitride) Layer
34: (Silicon) Layer
35: (Silicon) Layer
35: Substrate
36: (Silicon nitride) Layer
37: Insulation film
38: VCSEL substrate
39: LDD substrate
40: Laminated film
41: Active layer
42: Anode electrode
42a: Opening
43: GaAs layer
44: Cathode electrode
45: Resin member
46: Pad
47: Pad
48: Pillar
49: (Nickel) Layer
50: Solder layer
51: (Gold) Layer
52: Base layer
53: Insulation layer
54: Metal light shielding layer
55: Light transmission layer
56: Clad layer
57: Grating coupler
58: Grating coupler
59: Bragg mirror
60: Light shielding wall
62: Extraction portion
63: Electrode layer
64: Contact
65: Electrode
66: Reflection member
67: Light shielding resin layer
68: light refraction member
69: Protruded and recessed structure
70: Metal layer
70h: Hole
71: Metal nanoparticle
72: Substrate
73: AFE portion
74: Substrate
75: Support substrate
76: Reflection mirror
78: Optical lens
79: Optical fiber
80: Optical connector
81: Optical connector
82: Optical connector
83: First lens
83: Collimating lens
84: Second lens
85: Lens holder
86: Resistance element
87: Inverter
89: Reflection mirror
90: Transimpedance amplifier (TIA)
91: Threshold comparison circuit
92: Optical switch
94: Counter
95: Optical gate switch
95a: First introduction portion
95b: Emission portion
95c: Second introduction portion
96: Optical switch
96: Mach-Zehnder interference type optical switch
97: Directional coupling type optical switch
97a: First introduction portion (IN1)
97b: Second introduction portion (IN2)
97c: First emission portion (OUT1)
97d: Second emission portion (OUT2)

1. An optical detection device comprising:
a plurality of light emitting elements each of which emits a first light pulse signal;
a plurality of light propagation members that propagate the first light pulse signals emitted from the plurality of light emitting elements;
a plurality of first light receiving elements that receive the first light pulse signals propagated through the plurality of light propagation members;
a plurality of second light receiving elements that receive reflection light pulse signals obtained by the first light pulse signals emitted from the plurality of light emitting elements being reflected on an object; and
a plurality of light guide members that guide the first light pulse signals emitted from the plurality of light emitting elements to the plurality of light propagation members.

2. The optical detection device according to claim 1, wherein
each of the plurality of light emitting elements includes a laminate that includes an active layer and a light extraction portion, and
a part of the first light pulse signal emitted from the corresponding light extraction portion is introduced into each of the plurality of light propagation members.

3. The optical detection device according to claim 2, comprising:
a first substrate that supports a plurality of the laminates and transmits the first light pulse signal emitted from each of the light extraction portions; and
a plurality of electrodes disposed at ends of the plurality of laminates on a side opposite to the light extraction portions, wherein
the plurality of light propagation members are disposed along the first substrate.

4. The optical detection device according to claim 2, comprising:
a first substrate that is disposed on a side opposite to the light extraction portions of a plurality of the laminates and supports the plurality of laminates; and
a plurality of electrodes that are disposed on the first substrate and supply voltage to the plurality of laminates, wherein
the plurality of light propagation members are disposed along the first substrate.

5. The optical detection device according to claim 1, wherein
each of the plurality of light emitting elements includes a laminate that includes an active layer and a light extraction portion, and
each of the plurality of light propagation members propagates a part of the first light pulse signal emitted from the corresponding active layer.

6. The optical detection device according to claim 5, comprising:
a first substrate that supports the plurality of laminates and transmits the first light pulse signal emitted from each of the light extraction portions; and
a plurality of electrodes disposed at ends of the plurality of laminates on a side opposite to the light extraction portions, wherein
the plurality of light propagation members are disposed along a plurality of the active layers.

7. The optical detection device according to claim 5, comprising:
a first substrate that is disposed on a side opposite to the light extraction portions of a plurality of the laminates and supports the plurality of laminates; and
a plurality of electrodes disposed on the first substrate, wherein
the plurality of light propagation members are disposed along a plurality of the active layers.

8. The optical detection device according to claim 1, wherein
each of the plurality of light emitting elements includes a laminate that includes an active layer and a light extraction portion, and a light reflection member disposed on a side opposite to the light extraction portion with the active layer interposed between the light reflection member and the light extraction portion, and
each of the plurality of light propagation members propagates the first light pulse signal emitted from an opening formed at a part of the corresponding light reflection member.

9. The optical detection device according to claim 8, comprising:
a first substrate that supports the plurality of laminates and transmits the first light pulse signal emitted from each of the light extraction portions;
a plurality of electrodes disposed at ends of the plurality of laminates on a side opposite to the light extraction portions; and
a second substrate that generates voltage to be supplied to the plurality of electrodes, wherein
the plurality of light propagation members are disposed on the second substrate.

10. The optical detection device according to claim 8, comprising:
a first substrate that is disposed on a side opposite to the light extraction portions of a plurality of the laminates and supports the plurality of laminates;
a plurality of electrodes disposed on the first substrate; and
a second substrate that generates voltage to be supplied to the plurality of electrodes, wherein
the plurality of light propagation members are disposed on the second substrate.

11. The optical detection device according to claim 1, comprising:
a light emission substrate where the plurality of light emitting elements are disposed; and
a light reception substrate where the plurality of first light receiving elements and the plurality of second light receiving elements are disposed, wherein
each of the plurality of light propagation members is disposed in such a manner as to extend over the light emission substrate and the light reception substrate.

12. The optical detection device according to claim 1, comprising:
a substrate where the plurality of light emitting elements, the plurality of first light receiving elements, and the plurality of second light receiving elements are disposed, wherein
the plurality of light propagation members are disposed on the substrate.

13. The optical detection device according to claim 1, comprising:
a light emission substrate where the plurality of light emitting elements and the plurality of first light receiving elements are disposed; and
a light reception substrate where the plurality of second light receiving elements are disposed, wherein
each of the plurality of light propagation members is disposed in such a manner as to extend over the light emission substrate and the light reception substrate.

14. The optical detection device according to claim 11, wherein
the plurality of first light receiving elements are disposed closer to the plurality of light emitting elements than the plurality of second light receiving elements, and
the plurality of light propagation members are disposed from a region containing the plurality of light emitting elements to a region containing the plurality of first light receiving elements.

15. The optical detection device according to claim 1, comprising:
a light shielding member that shields light to prevent entrance of the first light pulse signals propagated through the plurality of light propagation members into the plurality of second light receiving elements.

16. The optical detection device according to claim 1, wherein each of the plurality of light guide members has a grating coupler.

17. The optical detection device according to claim 1, wherein each of the plurality of light guide members switches the first light pulse signals emitted from two or more of the light emitting elements to propagate the first light pulse signals.

18. The optical detection device according to claim 17, comprising:
two or more optical switches each of which is connected to the corresponding one of the plurality of light guide members, wherein
the first light pulse signals emitted from the two or more light emitting elements are sequentially introduced into the corresponding light guide member by sequentially turning on the two or more optical switches one by one.

19. The optical detection device according to claim 1, wherein each of the first light receiving elements includes an SPAD (Single Photon Avalanche photodiode), an SiPM (Silicon Photomultiplier), an iToF (indirect Time of Flight) sensor, or a photon count sensor.

20. The optical detection device according to claim 1, wherein each of the light propagation members has an optical waveguide, or an optical fiber and an optical connector.
